(19) United States
(12) Patent Application Publication
(10) Pub. No.: US 2018/0175272 A1
(43) Pub. Date: Jun. 21, 2018

(54) THERMOELECTRIC CONVERSION MODULE

(71) Applicant: FUJIFILM Corporation, Tokyo (JP)

(72) Inventors: Shinji IMAI, Kanagawa (JP); Hideyuki SUZUKI, Kanagawa (JP)

(73) Assignee: FUJIFILM Corporation, Tokyo (JP)

(21) Appl. No.: 15/898,317

(22) Filed: Feb. 16, 2018

Related U.S. Application Data
(63) Continuation of application No. PCT/JP2016/072078, filed on Jul. 27, 2016.

(30) Foreign Application Priority Data
Aug. 31, 2015 (JP) 2015-170568
May 31, 2016 (JP) 2016-108549

(51) Int. Cl. H01L 35/32; H01L 35/30; H01L 35/22

(52) U.S. Cl. CPC H01L 35/32; H01L 35/22; H01L 35/30

(57) ABSTRACT

A thermoelectric conversion module includes a thermoelectric conversion module body which includes a plurality of thermoelectric conversion module substrates in which at least one of a P-type thermoelectric conversion element having a P-type thermoelectric conversion layer and a pair of connection electrodes which are electrically connected to the P-type thermoelectric conversion layer, or an N-type thermoelectric conversion element having an N-type thermoelectric conversion layer and a pair of connection electrodes which are electrically connected to the N-type thermoelectric conversion layer is provided on one surface of an insulating substrate having flexibility, the plurality of thermoelectric conversion module substrates being arranged such that a direction of the connection electrode and a direction of the insulating substrate are aligned, and a heat transfer portion which is provided on a side of the thermoelectric conversion module body close to at least one connection electrode of the thermoelectric conversion module substrate, presses the thermoelectric conversion module substrate in an arrangement direction, and transfers heat to the thermoelectric conversion module body or dissipates heat of the thermoelectric conversion module body. A thermal conductivity of the heat transfer portion is 10 W/mK or higher. A normal stress in a direction perpendicular to a surface of the insulating substrate in a case of pressing the thermoelectric conversion module substrate in the arrangement direction by the heat transfer portion is 0.01 MPa or higher.

### CROSS-REFERENCE TO RELATED APPLICATIONS

This application is a Continuation of PCT International Application No. PCT/JP2016/072078 filed on Jul. 27, 2016, which claims priority under 35 U.S.C. § 119(a) to Japanese Patent Application No. 2015-170568 filed on Aug. 31, 2015 and Japanese Patent Application No. 2016-108549 filed on May 31, 2016. Each of the above applications is hereby expressly incorporated by reference, in its entirety, into the present application.

### BACKGROUND OF THE INVENTION

### 1. Field of the Invention

The present invention relates to a thermoelectric conversion module formed using a flexible insulating substrate and particularly relates to a thermoelectric conversion module exhibiting high power generation output.

### 2. Description of the Related Art

As a device capable of directly generating electricity from a temperature difference, a thermoelectric conversion device is known.

The defect of a thermoelectric conversion device having a thermoelectric conversion layer formed of BiTe in the related art is that so much time and labor is required for manufacture a large number of thermoelectric conversion layers being connected to each other in series. In addition, an influence of thermal strain or a change in thermal strain due to a difference in thermal expansion coefficient is repeatedly generated and thus a fatigue phenomenon at the interface between the thermoelectric conversion layers easily occurs.

As a method of solving such problems, there is proposed a thermoelectric conversion device produced by utilizing a flexible base material.

For example, JP2006-86510A discloses a thermoelectric conversion device formed by arranging a P-type thermoelectric conversion material member and an N-type thermoelectric conversion material member on an elongated flexible base material such that the thermoelectric conversion material members are alternately electrically connected to each other in series in an extending direction of a low thermal conductive base material of polyimide or the like and are thermally connected to each other in parallel in a width direction of the base material, and bending or winding the base material in a cylindrical shape. After the base material is wound, a heat transfer plate is provided in an upper portion and a lower portion.

Also, there is a case where a thermoelectric conversion device is formed by forming a film of a thermoelectric conversion material on a flexible base material and bending the base material while sandwiching the base material between heat insulating plates.

Since these thermoelectric conversion devices are produced by forming a structure in which a large number of thermoelectric conversion materials are connected to each other in series on a flexible base material, much less time and labor is required for producing a large number of connection portions for connecting a large number of thermoelectric conversion materials, compared to the above-described method. In addition, it is possible to form a device shape having a relatively high degree of freedom by deforming the base material itself even after a film of thermoelectric conversion material or wiring is formed by utilizing the base material having flexibility.

### SUMMARY OF THE INVENTION

However, in the configuration described in JP2006-86510A, since the low thermal conductive base materials of polyimide or the like are overlapped, a temperature difference is not easily generated in the overlapped thermoelectric conversion elements at the center of the base materials and thus the power generation amount of the entire thermoelectric conversion device is decreased.

In addition, since it is required to use resin for reinforcement between the overlapped thermoelectric conversion elements, heat insulating properties are decreased due to the resin, a temperature difference is not easily generated in the thermoelectric conversion layer, and thus the power generation amount of the entire thermoelectric conversion device is decreased.

In addition, since the electrodes of each thermoelectric conversion layer are formed to the base material end portion, it is required to provide an insulating protective member on the upper surface and the lower surface of the thermoelectric conversion device in an overlapped state to fix a heat source. The insulating protective member has high thermal resistance, a temperature difference is not easily generated in the thermoelectric conversion layer, and thus the power generation amount of the entire thermoelectric conversion device is decreased.

An object of the present invention is to solve the above-described problems in the related art and to provide a thermoelectric conversion module which exhibits high power generation output.

In order to achieve the above object, according to the present invention, there is provided a thermoelectric conversion module comprising: a thermoelectric conversion module body which includes a plurality of thermoelectric conversion module substrates in which at least one of a P-type thermoelectric conversion element having a P-type thermoelectric conversion layer and a pair of connection electrodes which are electrically connected to the P-type thermoelectric conversion layer, or an N-type thermoelectric conversion element having an N-type thermoelectric conversion layer and a pair of connection electrodes which are electrically connected to the N-type thermoelectric conversion layer is provided on one surface of an insulating substrate having flexibility, the plurality of thermoelectric conversion module substrates being arranged such that a direction of the connection electrode and a direction of the insulating substrate are aligned; and a heat transfer portion which is provided on a side of the thermoelectric conversion module body close to at least one connection electrode of the thermoelectric conversion module substrate, presses the thermoelectric conversion module substrate in an arrangement direction, and transfers heat to the thermoelectric conversion module body or dissipates heat of the thermoelectric conversion module body, in which a thermal conductivity of the heat transfer portion is 10 W/mK or higher, and a normal stress in a direction perpendicular to a surface of the insulating substrate in a case of pressing the thermoelectric conversion module substrate in the arrangement direction by the heat transfer portion is 0.01 MPa or higher.

According to the present invention, there is provided a thermoelectric conversion module comprising: a thermoelectric conversion module body including a thermoelectric conversion module substrate which has a P-type thermoelectric conversion element having a P-type thermoelectric conversion layer and a pair of connection electrodes which are electrically connected to the P-type thermoelectric conversion layer, and an N-type thermoelectric conversion element having an N-type thermoelectric conversion layer and a pair of connection electrodes which are electrically connected to the N-type thermoelectric conversion layer provided on one surface of one insulating substrate having flexibility, and is alternately mountain-folded and valley-folded at the connection electrodes and formed in a bellows structure; and a heat transfer portion which is provided on a side of the thermoelectric conversion module body close to at least one connection electrode of the thermoelectric conversion module substrate, presses the thermoelectric conversion module substrate in an arrangement direction, and transfers heat to the thermoelectric conversion module body or dissipates heat of the thermoelectric conversion module body, in which a thermal conductivity of the heat transfer portion is 10 W/mK or higher, and a normal stress in a direction perpendicular to a surface of the insulating substrate in a case of pressing the thermoelectric conversion module substrate in the arrangement direction by the heat transfer portion is 0.01 MPa or higher.

It is preferable that the heat transfer portions are provided on sides of the thermoelectric conversion module body close to the both connection electrodes of the thermoelectric conversion module substrate, one heat transfer portion transfers heat to the thermoelectric conversion module body, and the other heat transfer portion dissipates heat of the thermoelectric conversion module body.

For example, the heat transfer portion has a frame portion in contact with a thermoelectric conversion module body.

For example, the heat transfer portion has a bellows structure body in which the connection electrode of the thermoelectric conversion module substrate of the thermoelectric conversion module body is sandwiched.

It is preferable that the heat transfer portion has a frame portion in contact with the thermoelectric conversion module body and a bellows structure body in which the connection electrode of the thermoelectric conversion module substrate of the thermoelectric conversion module body is sandwiched.

In addition, the thermoelectric conversion module substrate of the thermoelectric conversion module body is formed in a bellows-like shape.

It is preferable that the P-type thermoelectric conversion element and the N-type thermoelectric conversion element which are connected to each other in series by the connection electrodes are provided on the thermoelectric conversion module substrate.

It is preferable that the thermoelectric conversion module substrate on which only the P-type thermoelectric conversion element is provided and the thermoelectric conversion module substrate on which only the N-type thermoelectric conversion element is provided are alternately arranged in the arrangement direction in the thermoelectric conversion module body.

According to the present invention, it is possible to obtain a thermoelectric conversion module which exhibits high power generation output.

### BRIEF DESCRIPTION OF THE DRAWINGS

FIG. 1 is a schematic cross-sectional view showing a first example of a thermoelectric conversion device having a thermoelectric conversion module according to an embodiment of the present invention.

FIG. 2 is a schematic view showing a first example of a thermoelectric conversion module substrate of the thermoelectric conversion module according to the embodiment of the present invention.

FIG. 3 is a schematic view showing a second example of the thermoelectric conversion module substrate of the thermoelectric conversion module according to the embodiment of the present invention.

FIG. 4 is a schematic view showing a third example of the thermoelectric conversion module substrate of the thermoelectric conversion module according to the embodiment of the present invention.

FIG. 5 is a schematic cross-sectional view showing a first example of a thermoelectric conversion module body of the thermoelectric conversion module according to the embodiment of the present invention.

FIG. 6 is a schematic cross-sectional view showing a second example of the thermoelectric conversion module body of the thermoelectric conversion module according to the embodiment of the present invention.

FIG. 7 is a schematic cross-sectional view showing a fourth example of the thermoelectric conversion module substrate of the thermoelectric conversion module according to the embodiment of the present invention.

FIG. 8 is a schematic view showing a heat transfer portion of the thermoelectric conversion module according to the embodiment of the present invention.

FIG. 9 is a schematic view showing another example of the thermoelectric conversion module according to the embodiment of the present invention.

FIG. 10 is a schematic view showing another configuration of the heat transfer portion of the thermoelectric conversion module according to the embodiment of the present invention.

FIG. 11 is a schematic cross-sectional view showing another configuration of the heat transfer portion of the thermoelectric conversion module according to the embodiment of the present invention.

FIG. 12 is a schematic view showing still another example of the thermoelectric conversion module according to the embodiment of the present invention.

FIG. 13 is a schematic cross-sectional view showing a thermoelectric conversion device having another example of the thermoelectric conversion module according to the embodiment of the present invention.

FIG. 14 is a schematic cross-sectional view showing another thermoelectric conversion device having another example of the thermoelectric conversion module according to the embodiment of the present invention.

FIG. 15 is a schematic cross-sectional view showing a second example of the thermoelectric conversion device having the thermoelectric conversion module according to the embodiment of the present invention.

FIG. 16 is a schematic cross-sectional view showing a third example of the thermoelectric conversion device having the thermoelectric conversion module according to the embodiment of the present invention.

FIG. 17 is a schematic cross-sectional view showing a fourth example of the thermoelectric conversion device having the thermoelectric conversion module according to the embodiment of the present invention.

FIG. 18 is a schematic cross-sectional view showing a fifth example of the thermoelectric conversion device having the thermoelectric conversion module according to the embodiment of the present invention.

FIG. 19 is a schematic cross-sectional view showing a sixth example of the thermoelectric conversion device having the thermoelectric conversion module according to the embodiment of the present invention.

FIG. 20 is a schematic cross-sectional view showing a seventh example of the thermoelectric conversion device having the thermoelectric conversion module according to the embodiment of the present invention.

### DESCRIPTION OF THE PREFERRED EMBODIMENTS

Hereinafter, a thermoelectric conversion module of the present invention will be described in detail based on preferable embodiments shown in the accompanying drawings.

In the following description, “to” indicating a numerical value range includes numerical values described on both sides. For example, when ε is a numerical value α to a numerical value β, the range of ε is a range including the numerical value α and the numerical value β, and is represented as a α≤ε≤β using mathematical symbols.

Unless otherwise specified, an angle such as “perpendicular”, or “orthogonal” means that a difference from the exact angle falls within a range of less than 5°. The difference from the exact angle is preferably less than 40 and more preferably less than 3.

The meaning of “the same” includes an error range that is generally allowable in the technical field. In addition, the meaning of “all” or “entire surface” includes not only 100% but also a case where an error range is generally allowable in the technical field, for example, 99% or more, 95% or more, or 90% or more.

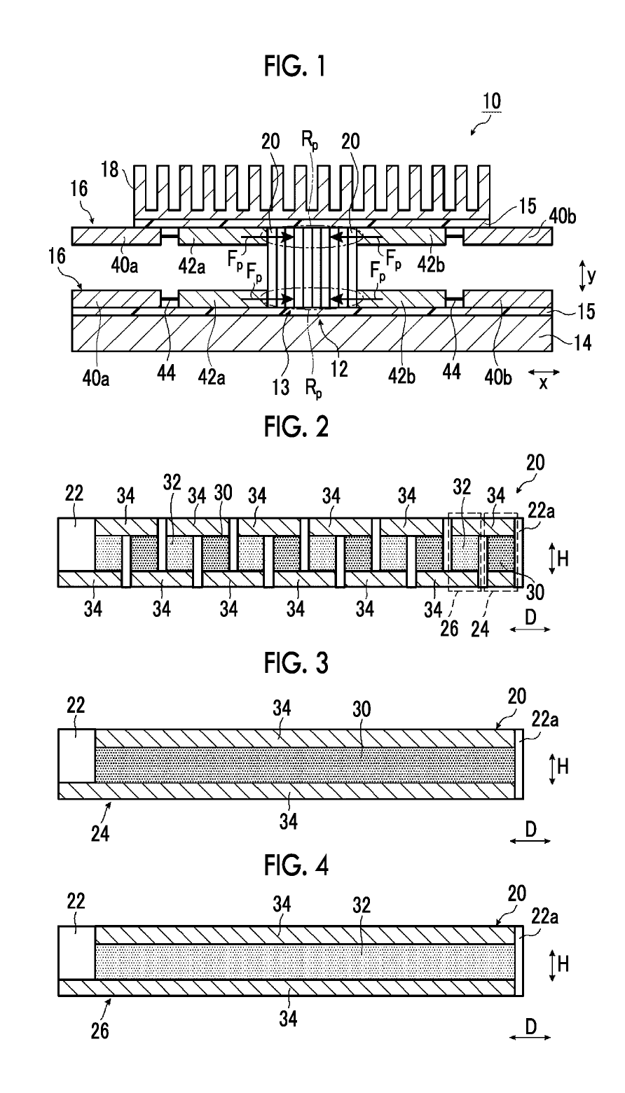

FIG. 1 is a schematic cross-sectional view showing a first example of a thermoelectric conversion device having a thermoelectric conversion module according to an embodiment of the present invention.

A thermoelectric conversion device 10 shown in FIG. 1 generates power by a thermoelectric conversion module 12 by using a temperature difference. The thermoelectric conversion device 10 has the thermoelectric conversion module 12, a base 14, and a heat dissipating fin 18.

On the base 14, the thermoelectric conversion module 12 is placed. For example, a thermally conductive sheet 15 is provided between the base 14 and the thermoelectric conversion module 12.

The heat dissipating fin 18 is provided on the thermoelectric conversion module 12 for dissipating heat of the thermoelectric conversion module 12. The thermally conductive sheet 15 is provided between the heat dissipating fin 18 and the thermoelectric conversion module 12.

The base 14 is formed of, for example, a material having high thermal conductivity, such as metal or an alloy. For example, the temperature of the base 14 is set to a relatively high temperature, a temperature difference is generated in the thermoelectric conversion module 12 in a y direction (refer to FIG. 1), and power is generated by the thermoelectric conversion module 12 to obtain power generation output.

Hereinafter, the thermoelectric conversion module 12 will be described.

The thermoelectric conversion module 12 has a thermoelectric conversion module body 13 and a heat transfer portion 16.

Although described in detail later, in the thermoelectric conversion module body 13, a plurality of thermoelectric conversion module substrates 20 are arranged in an x direction such that a pair of connection electrodes 34 of the thermoelectric conversion module substrate 20 (refer to FIG. 2) are aligned in a y direction. The x direction is a direction orthogonal to the y direction. The x direction is referred to as an arrangement direction.

The heat transfer portion 16 is provided on a side of the thermoelectric conversion module body 13 close to at least one connection electrode 34 (refer to FIG. 2) of the thermoelectric conversion module substrate 20 (refer to FIG. 2), presses the thermoelectric conversion module substrate 20 in the arrangement direction with a pressing force Fp, and transfers heat to the thermoelectric conversion module body 13 or dissipates heat of the thermoelectric conversion module body 13.

In the thermoelectric conversion module 12 in FIG. 1, the heat transfer portions 16 are provided on sides of the thermoelectric conversion module body 13 close to the both connection electrodes 34 (refer to FIG. 2) of the thermoelectric conversion module substrate 20 (refer to FIG. 2). That is, the heat transfer portions 16 are provided at both ends of the thermoelectric conversion module body 13 in the y direction.

In a case where the temperature of a side of the thermoelectric conversion module 12 close to the base 14 is set to a relatively high temperature, the heat transfer portion 16 on a side close to the base 14 transfers heat to the thermoelectric conversion module body 13 and the heat transfer portion 16 on a side close to the heat dissipating fin 18 dissipates heat of the thermoelectric conversion module body 13.

Next, the thermoelectric conversion module body 13 will be described.

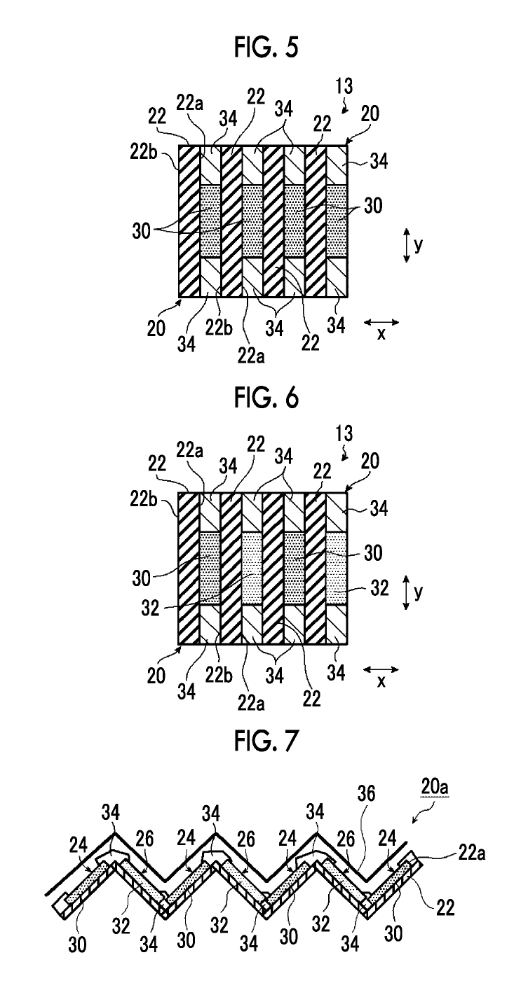

FIG. 2 is a schematic view showing a first example of a thermoelectric conversion module substrate of the thermoelectric conversion module according to the embodiment of the present invention, FIG. 3 is a schematic view showing a second example of the thermoelectric conversion module substrate of the thermoelectric conversion module according to the embodiment of the present invention, and FIG. 4 is a schematic view showing a third example of the thermoelectric conversion module substrate of the thermoelectric conversion module according to the embodiment of the present invention. FIG. 5 is a schematic cross-sectional view showing a first example of a thermoelectric conversion module body of the thermoelectric conversion module according to the embodiment of the present invention, and FIG. 6 is a schematic cross-sectional view showing a second example of the thermoelectric conversion module body of the thermoelectric conversion module according to the embodiment of the present invention.

The thermoelectric conversion module body 13 is formed such that the plurality of thermoelectric conversion module substrates 20 are overlapped and arranged in the arrangement direction.

As shown in FIG. 2, for example, in the thermoelectric conversion module substrate 20, a P-type thermoelectric conversion element 24 and an N-type thermoelectric conversion element 26 are provided to be connected to each other in series by the connection electrodes 34 on a surface 22a of an insulating substrate 22. The connection electrodes 34 are separately provided in both end portions of the insulating substrate 22 in a direction H orthogonal to a longitudinal direction D.

The insulating substrate 22 has flexibility. The insulating substrate 22 will be described in detail later. The surface 22a of the insulating substrate 22 corresponds to one surface.

Herein, the flexibility refers to the ability of the substrate to be bent and folded without being broken.

The P-type thermoelectric conversion element 24 has a P-type thermoelectric conversion layer 30, and a pair of the connection electrodes 34. The connection electrodes 34 are electrically connected to both sides of the P-type thermoelectric conversion layer 30.

The N-type thermoelectric conversion element 26 has an N-type thermoelectric conversion layer 32 and a pair of the connection electrodes 34. The connection electrodes 34 are electrically connected to both sides of the N-type thermoelectric conversion layer 32.

For example, a plurality of thermoelectric conversion module substrates 20 shown in FIG. 2 are arranged such that the direction of the connection electrode 34 and the direction of the insulating substrate 22 are aligned, and the P-type thermoelectric conversion element 24 and the N-type thermoelectric conversion element 26 are directed to a rear surface 22b of the insulating substrate 22 to form a thermoelectric conversion module body 13 having a configuration shown in FIG. 5.

As shown in FIG. 3, the thermoelectric conversion module substrate 20 may adopt a structure in which only the P-type thermoelectric conversion element 24 is provided on the surface 22a of the insulating substrate 22. In this case, the connection electrodes 34 are provided at both end portions in the direction H and extend in the longitudinal direction D of the insulating substrate 22, and only the P-type thermoelectric conversion layer 30 is provided between the pair of connection electrodes 34.

In addition, as shown in FIG. 4, the thermoelectric conversion module substrate 20 may adopt a structure in which only the N-type thermoelectric conversion element 26 is provided on the surface 22a of the insulating substrate 22. In this case, the connection electrodes 34 are provided at both end portions in the direction H and extend in the longitudinal direction D of the insulating substrate 22, and only the N-type thermoelectric conversion layer 32 is provided between the pair of connection electrodes 34.

A thermoelectric conversion module body 13 having a configuration shown in FIG. 6 may be formed in such a manner that a plurality of thermoelectric conversion module substrates 20 on which only the P-type thermoelectric conversion element 24 is formed as shown in FIG. 3 and thermoelectric conversion module substrates 20 on which only the N-type thermoelectric conversion element 26 is formed shown in FIG. 4 are alternately arranged such that the direction of the connection electrode 34 and the direction of the insulating substrate 22 are aligned, and each thermoelectric conversion element is directed to the rear surface 22b of the insulating substrate 22.

Since the number of thermoelectric conversion elements connected to each other in series is large in the thermoelectric conversion module body 13 shown in FIG. 5 compared to the thermoelectric conversion module body 13 shown in FIG. 6, a high power generation voltage can be obtained.

In addition, the thermoelectric conversion module substrate 20 is not limited to a configuration of a single plate. Herein, FIG. 7 is a schematic cross-sectional view showing a fourth example of the thermoelectric conversion module substrate of the thermoelectric conversion module according to the embodiment of the present invention.

For example, as shown in FIG. 7, a bellows-like thermoelectric conversion module substrate 20a may be used. In the thermoelectric conversion module substrate 20a shown in FIG. 7, the P-type thermoelectric conversion element 24 and the N-type thermoelectric conversion element 26 are alternately provided on the surface 22a of one insulating substrate 22 while sandwiching the connection electrode 34 therebetween. The thermoelectric conversion module substrate 20a is formed in a bellows structure such that one insulating substrate 22 is repeatedly mountain-folded and valley-folded, or valley-folded and mountain-folded at the connection electrodes 34. In addition, in the thermoelectric conversion module substrate 20a, an insulating sheet 36 is provided so as to cover the P-type thermoelectric conversion element 24 and the N-type thermoelectric conversion element 26.

In a case where a bellows structure is formed as in the thermoelectric conversion module substrate 20a, excessive bending of the insulating substrate 22 causes contact of the P-type thermoelectric conversion element 24 and the N-type thermoelectric conversion element 26 facing each other so as to cause a short circuit. However, a short circuit can be prevented by providing the insulating sheet 36.

As the insulating sheet 36, an insulating sheet having such a degree of insulating properties that a short circuit of the P-type thermoelectric conversion element 24 and the N-type thermoelectric conversion element 26 can be prevented can be appropriately used. For the insulating sheet 36, for example, polyimide is used.

In the bellows-like thermoelectric conversion module substrate 20a, the thermoelectric conversion module body 13 can be obtained by folding one insulating substrate 22 to alternately form a mountain fold portion and a valley fold portion at the connection electrodes 34. In the thermoelectric conversion module substrate 20a, the insulating substrate is folded as described above, and a direction in which the bellows expands or contracts refers to a folding direction. This folding direction is the same direction as the above-described arrangement direction.

Next, the heat transfer portion 16 will be described.

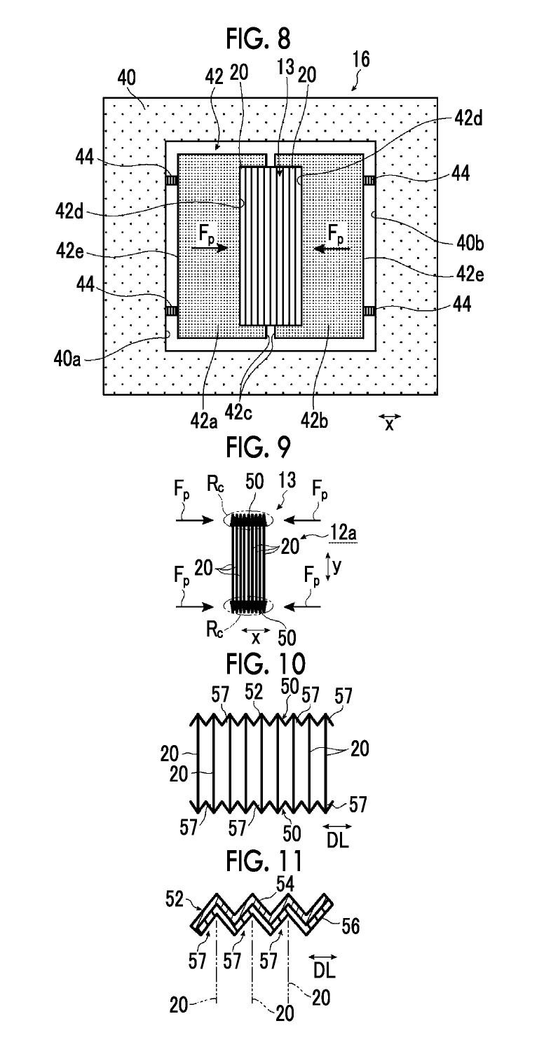

FIG. 8 is a schematic view showing a heat transfer portion of the thermoelectric conversion module according to the embodiment of the present invention.

The heat transfer portion 16 shown in FIG. 8 has an outer frame 40 having a rectangular external shape, and a frame portion 42 having a rectangular external shape arranged in the outer frame 40. The outer frame 40 surrounds the frame portion 42 and is arranged with a gap. The outer frame 40 is constituted of, for example, a flat plate-like frame material having a predetermined width.

The frame portion 42 is in contact with the thermoelectric conversion module body 13 and surrounds the periphery of the thermoelectric conversion module body 13, for example. The frame portion 42 has a first frame material 42a having a recessed portion 42d formed along the shape of the thermoelectric conversion module body 13 and a second frame material 42b, and the first frame material 42a and the second frame material 42b are arranged to face to each other and end surfaces 42c are separated from each other. The first frame material 42a and the second frame material 42b are constituted of, for example, a flat plate.

Regarding the outer frame 40 and the first frame material 42a, an inner surface 40a of the outer frame 40 and an outer surface 42e of the first frame material 42a facing each other are connected by screws 44. By rotating the screws 44, the first frame material 42a can be moved toward the second frame material 42b. Regarding the outer frame 40 and the second frame material 42b, an inner surface 40b of the outer frame 40 and an outer surface 42e of the second frame material 42b facing each other are connected by the screws 44. By rotating the screws 44, the second frame material 42b can be moved toward the first frame material 42a. Thus, the thermoelectric conversion module body 13 can be pressed by the frame portion 42 with a pressing force Fp in the arrangement direction, that is, in the x direction.

Both the outer frame 40 and the frame portion 42 have a rectangular external shape. However, there is no limitation thereto and may be a circular shape or an elliptical shape. In addition, for example, any screw may be used as the screw 44.

The heat transfer portion 16 has the outer frame 40 and the frame portion 42. However, there is no limitation thereto and as long as the thermoelectric conversion module body 13 can be pressed with a normal stress of 0.01 MPa or higher as described later, only frame portion 42 may be provided.

The heat transfer portion 16 is constituted of a high thermal conductive material having a thermal conductivity of 10 W/mK or higher. In the heat transfer portion 16, the thermal conductivity of the frame portion 42 in contact with at least the thermoelectric conversion module body 13 may be 10 W/mK or higher. As long as the thermal conductivity of the heat transfer portion 16 is 10 W/mK or higher, a large amount of heat can be supplied to the thermoelectric conversion module body 13 from a high temperature side. In addition, a large amount of heat can be discharged to a low temperature side.

On the other hand, in a case where the thermal conductivity is lower than 10 W/mK, the supply of the amount of heat and the discharge of the amount of heat described above are not enough.

The value of the thermal conductivity of the heat transfer portion 16 described above is a published value such as value of the thermal conductivity described in Handbook of Physical Properties or a value of thermal conductivity released by manufacturers.

The thermoelectric conversion module 12 has the thermoelectric conversion module body 13 and the heat transfer portion 16 as described above.

In the thermoelectric conversion module 12, in a case of pressing the thermoelectric conversion module substrate 20 in the arrangement direction by the heat transfer portion 16, the normal stress in a direction perpendicular to the surface 22a of the insulating substrate 22, that is, in the x direction is 0.01 MPa or higher.

More specifically, the normal stress is a value of stress in a direction perpendicular to the surface 22a of the insulating substrate 22 in a portion Rp in which the thermoelectric conversion module body 13 is sandwiched between the first frame material 42a and the second frame material 42b.

Since the above-described normal stress is 0.01 MPa or higher, a sufficient pressing force Fp to the thermoelectric conversion module body 13 is obtained and thus a temperature difference in the thermoelectric conversion module body 13 in the y direction can be increased. In addition, even in a case where flexibility is applied to the insulating substrate 22, the thermoelectric conversion module body 13 is erected independently. The upper limit of the normal stress is, for example, 300 MPa.

The above-described normal stress is a stress value measured by arranging PRESCALE (trade name, two-sheet type super low pressure (LLW), manufactured by Fujifilm Corporation) between the thermoelectric conversion module substrates at the center of the thermoelectric conversion module body 13. In a range of a small stress of 0.01 to 0.5 MPa, or the like, stress is measured by combining PRESCALE MAT (micropressure mat (5 mm), manufactured by Fujifilm Corporation) with protrusions made of rubber and PRESCALE in an overlapped manner.

Regarding adjustment of the above-described normal stress using the outer frame 40 and the frame portion 42, in a state in which only PRESCALE is arranged or PRESCALE and PRESCALE MAT are arranged, tightening of the screw 44 and a relationship between of an amount of tightening of the screw 44 and the normal stress are obtained in advance and the amount of tightening of the screw 44 is changed. Then, the normal stress can be adjusted.

In the thermoelectric conversion module 12, regarding the heat transfer portion 16, for example, in a case where in the configuration of the thermoelectric conversion device 10 shown in FIG. 1, the side of the thermoelectric conversion module close to the base 14 is set to a relatively high temperature side by bringing the base 14 in contact with a heat source, and the side of the thermoelectric conversion module close to the heat dissipating fin 18 is set to a low temperature side, in the thermoelectric conversion device 10 shown in FIG. 1, the frame portion 42 of the heat transfer portion 16 transfers heat on the side close to the base 14 to the thermoelectric conversion module body 13. In this case, since the frame portion 42 has a high thermal conductivity, the heat on the side close to the base 14 can be transferred to the thermoelectric conversion module body 13 with high efficiency and the temperature of the thermoelectric conversion module body 13 on the side close to the base 14 can be increased. In addition, since the heat transfer portion 16 is provided on a side close to one connection electrode 34 and the thermal conductivity of the connection electrode 34 is higher than that of the insulating substrate 22, the heat flow of the thermoelectric conversion module body 13 can be increased.

On the other hand, the heat of the thermoelectric conversion module body 13 is transferred to the frame portion 42 of the heat transfer portion 16 on the side close to the heat dissipating fin 18. In this case, since the frame portion 42 has a high thermal conductivity, the heat of the thermoelectric conversion module body 13 can be transferred to the heat dissipating fin 18 with high efficiency and a large amount of heat can be dissipated from the thermoelectric conversion module body 13. Thus, the temperature of the thermoelectric conversion module body 13 on the side close to the heat dissipating fin 18 can be decreased. Therefore, even in a case of using the insulating substrate 22, a temperature difference in the thermoelectric conversion module body 13 in the y direction can be further increased and the power generation output by the thermoelectric conversion module 12 can be further increased.

In the thermoelectric conversion module 12 shown in FIG. 1, the heat transfer portions 16 are provided at both ends of the thermoelectric conversion module body 13 in the y direction, but as described above, the heat transfer portion may be provided at least one of both ends of the thermoelectric conversion module body 13 in the y direction. By providing the heat transfer portion 16 on one end, the temperature of the thermoelectric conversion module body 13 of the high temperature side can be increased or the temperature of the thermoelectric conversion module body 13 of the low temperature side can be decreased. Thus, a temperature difference in the thermoelectric conversion module body 13 in the y direction can be increased and the power generation output by the thermoelectric conversion module 12 can be increased.

The configuration of the heat transfer portion 16 is not limited to the above configuration having the outer frame 40 and the frame portion 42 and may be configurations of a heat transfer portion 50 shown in FIGS. 9 to 12.

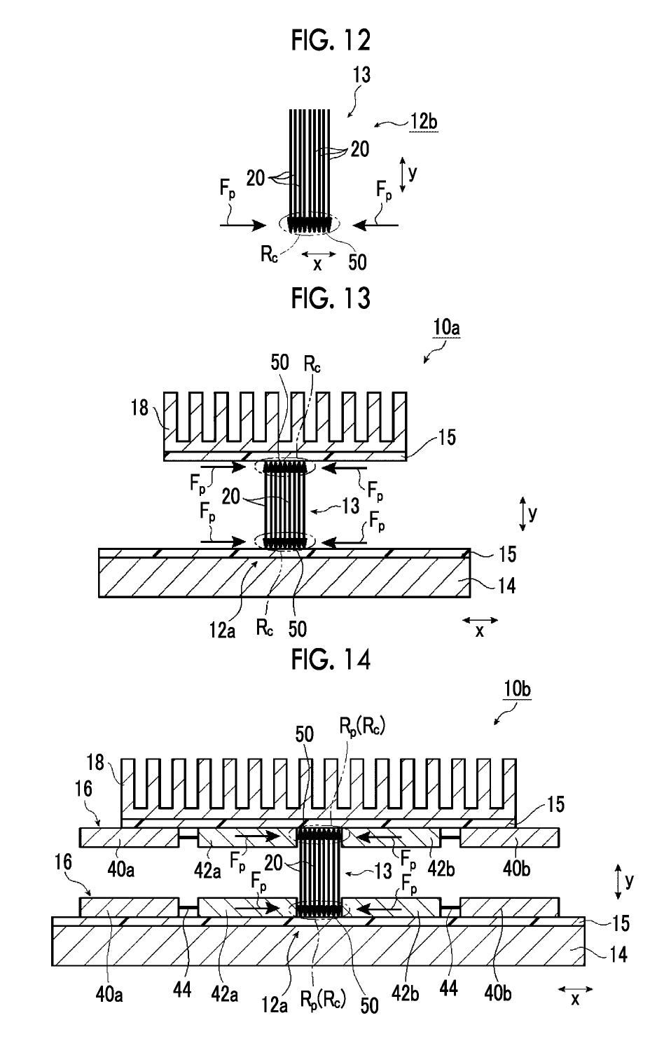

Herein, FIG. 9 is a schematic view showing another example of the thermoelectric conversion module according to the embodiment of the present invention, FIG. 10 is a schematic view showing another configuration of the heat transfer portion of the thermoelectric conversion module according to the embodiment of the present invention, FIG. 11 is a schematic cross-sectional view showing another configuration of the heat transfer portion of the thermoelectric conversion module according to the embodiment of the present invention, and FIG. 12 is a schematic view showing another example of the thermoelectric conversion module according to the embodiment of the present invention.

As in a thermoelectric conversion module 12a shown in FIG. 9, a configuration in which a plurality of thermoelectric conversion module substrates 20 are arranged in the arrangement direction and heat transfer portions 50 are provided on both sides of the thermoelectric conversion module substrate 20 may be adopted. As shown in FIG. 10, the heat transfer portion 50 has a bellows structure body 52 in which a mountain fold portion and a valley fold portion are repeatedly connected. The bellows structure body 52 is expandable in a direction DL in which the mountain fold portion and the valley fold portion are connected to each other, and the connection electrode 34 (refer to FIG. 2) of the thermoelectric conversion module substrate 20 of the thermoelectric conversion module body 13 can be sandwiched in an inner portion 57 of the mountain fold portion in the arrangement direction. The plurality of thermoelectric conversion module substrates 20 can be sandwiched by gripping the bellows structure body 52 with a vise or the like.

In the thermoelectric conversion module 12a shown in FIG. 9, by sandwiching the plurality of thermoelectric conversion module substrates 20 in the bellows structure body 52, the thermoelectric conversion module body can be pressed with a pressing force Fp in the arrangement direction. Thus, the normal stress in a direction perpendicular to the surface 22a (refer to FIG. 2) of the insulating substrate 22 can be set to 0.01 MPa or more. In the thermoelectric conversion module 12a shown in FIG. 9, by pressing the plurality of thermoelectric conversion module substrates 20 in the bellows structure body 52, a portion Rc of the bellows structure body 52 in the end portion of the insulating substrate 22 corresponds to the above-described portion Rp in which the thermoelectric conversion module body 13 is sandwiched between the first frame material 42a and the second frame material 42b.

Regarding the above-described adjustment of the normal stress using the bellows structure body 52, in a state in which PRESCALE is arranged, the bellows structure body 52 is gripped, and a relationship between a force at the time of gripping and the normal stress is obtained in advance. Then, the normal stress can be adjusted by changing the force at the time of gripping bellows structure body 52. In a case of using the bellows structure body 52, the stress is measured by using only PRESCALE or combining PRESCALE and PRESCALE MAT according to the stress range.

The bellows structure body 52 is a laminated structure body of an insulating layer 56 and a conductive layer 54 as shown in FIG. 11. The insulating layer 56 is constituted of, for example, polyimide, and the conductive layer 54 is constituted of, for example, aluminum. Since the bellows structure body 52 is formed by arranging the insulating layer 56 on a side close to the thermoelectric conversion module substrate 20, a short circuit between the thermoelectric conversion module substrates 20 is prevented and thermal conductivity is secured. The configurations of the insulating layer 56 and the conductive layer 54 are not limited to the above configurations. The bellows structure body 52 has a thermal conductivity of 10 W/mK or higher as in the above-described heat transfer portion 16.

In the example shown in FIG. 9, the heat transfer portions 50 are provided on both sides of the thermoelectric conversion module body 13, but there is no limitation thereto. As in the thermoelectric conversion module 12b shown in FIG. 12, the heat transfer portion may be provided on a side close to one connection electrode 34 of the thermoelectric conversion module substrate 20 of the thermoelectric conversion module body 13. In the example shown in FIG. 12, the portion Rc of the bellows structure body 52 in one end portion of the insulating substrate 22 corresponds to the above-described portion Rp in which the thermoelectric conversion module body 13 is sandwiched between the first frame material 42a and the second frame material 42b.

In addition, in the heat transfer portion 50, the thermoelectric conversion module substrates 20 are arranged in the entire inner portions 57 of the bellows structure body 52 but there is no limitation thereto. The thermoelectric conversion module substrates 20 are not required to be arranged in the entire inner portions 57, and there may be the inner portion 57 in which the thermoelectric conversion module substrate 20 is not arranged.

In the thermoelectric conversion module 12a shown in FIG. 9, instead of arrangement of the plurality of single plate thermoelectric conversion module substrates 20 as described above, the bellows-like thermoelectric conversion module substrate 20a may be used. Even in a case of applying flexibility to the insulating substrate 22 of the thermoelectric conversion module substrate 20, the bellows structure body 52 holds the thermoelectric conversion module substrate 20 and thus the thermoelectric conversion module body 13 is erected independently.

In a case of using the heat transfer portion 50, a configuration of a thermoelectric conversion device 10a shown in FIG. 13 is obtained. In a case where a side of the thermoelectric conversion device 10a close to the base 14 is set to a high temperature side, the heat on the high temperature side is transferred to the thermoelectric conversion module body 13 by the heat transfer portion 50 and the heat of the thermoelectric conversion module body 13 is dissipated to the heat dissipating fin 18. Since the bellows structure body 52 is connected to the connection electrode 34 of the thermoelectric conversion module substrate 20 and the thermal conductivity of the connection electrode 34 is higher than that of the insulating substrate 22, the heat transfer portion 50 makes it possible to further increase a temperature difference in the thermoelectric conversion module body 13 in the y direction and to further increase power generation output. Even in a case where the heat transfer portion 50 is provided on only one side of the thermoelectric conversion module body 13, as in a case of using the heat transfer portion 16, the power generation output can be increased.

Further, the heat transfer portion 16 and the heat transfer portion 50 may be combined. In this case, instead of arranging the thermoelectric conversion module body 13 shown in FIG. 1, the thermoelectric conversion module 12a shown in FIG. 9 is arranged to constitute the thermoelectric conversion device 10b shown in FIG. 14. In the example shown in FIG. 14, since the heat transfer portion 16 and the heat transfer portion 50 are provided, the portion Rp sandwiched between the first frame material 42a and the second frame material 42b described above and the portion Rc of the bellows structure body 52 are overlapped.

In the thermoelectric conversion device 10a shown in FIG. 13 and the thermoelectric conversion device 10b shown in FIG. 14 described above, the same symbols are attached to the same structures as in the thermoelectric conversion device 10 shown in FIG. 1, and the detailed descriptions thereof are omitted.

In the thermoelectric conversion device 10b shown in FIG. 14, as described above, the heat on the side close to the base 14 can be transferred to the thermoelectric conversion module body 13 with higher efficiency, and the temperature on the side of the thermoelectric conversion module body 13 close to the base 14 can be further increased. On the other hand, on the side close to the heat dissipating fin 18, the heat of the thermoelectric conversion module body 13 can be transferred to the heat dissipating fin 18 with higher efficiency, and a larger amount of heat can be dissipated from the thermoelectric conversion module body 13. Thus, the temperature on the side of the thermoelectric conversion module body 13 close to the heat dissipating fin 18 can be further decreased. Therefore, a temperature difference in the thermoelectric conversion module body 13 in the y direction can be further increased and thus power generation output can be further increased.

Hereinafter, specific examples of the thermoelectric conversion device will be further described.

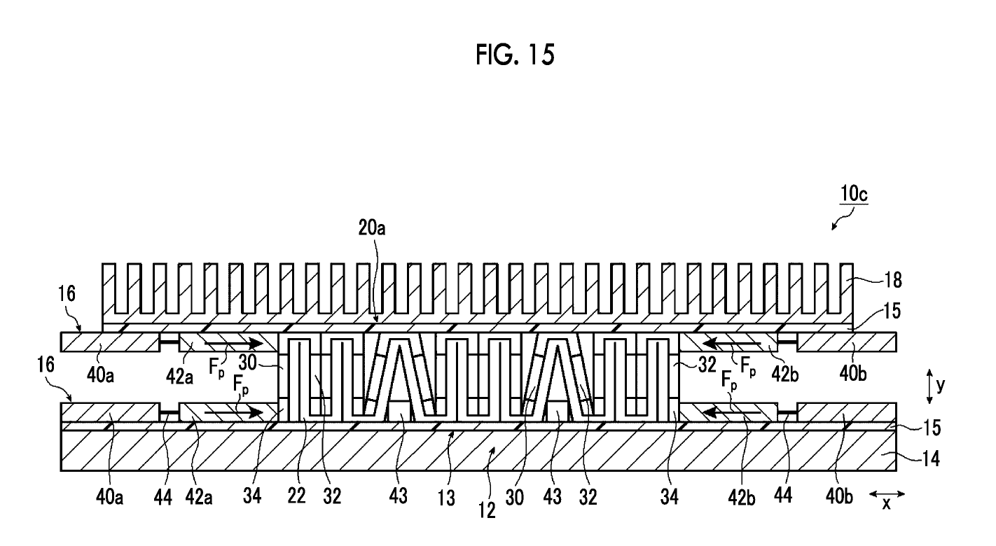

FIG. 15 is a schematic view showing a second example of the thermoelectric conversion device having the thermoelectric conversion module according to the embodiment of the present invention. In a thermoelectric conversion device 10c shown in FIG. 15, the same symbols are attached to the same structures as in the thermoelectric conversion device 10 shown in FIG. 1 and the thermoelectric conversion module substrate 20a shown in FIG. 7, and the detailed descriptions thereof are omitted.

The thermoelectric conversion device 10c shown in FIG. 15 is different from the thermoelectric conversion device 10 shown in FIG. 1 in that the thermoelectric conversion module body 13 is constituted of the bellows-like thermoelectric conversion module substrate 20a shown in FIG. 7. In the thermoelectric conversion module body 13, for example, two heat transfer members 43 are provided on the bellows-like thermoelectric conversion module substrate 20a in the x direction, and there are three partitioned regions. The heat transfer member 43 is constituted of a high thermal conductive material having a thermal conductivity of 10 W/mK or higher as in the case of the heat transfer portion 16. The heat transfer members 43 are included in the heat transfer portion 16.

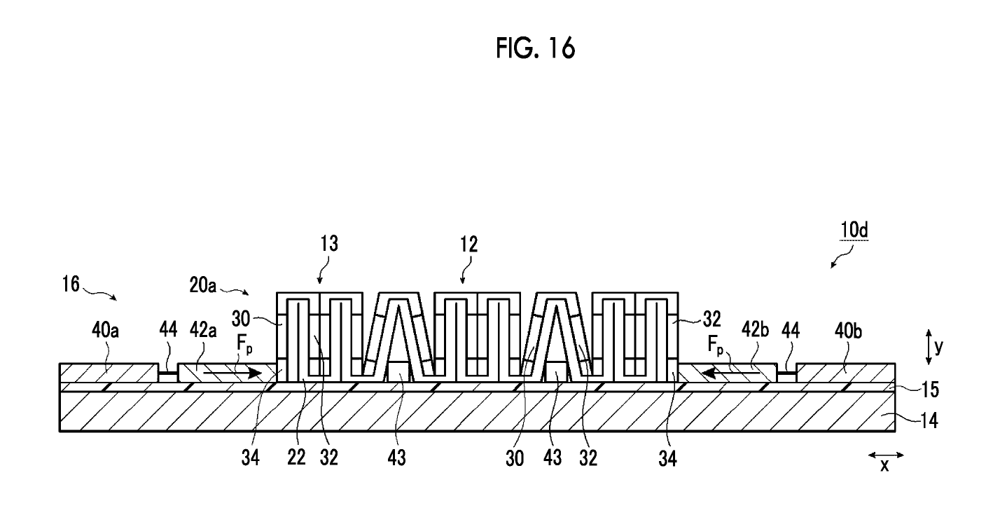

As shown in the thermoelectric conversion device 10c, even in a case where the thermoelectric conversion module substrate 20a is long, the heat source temperature can be effectively supplied to the thermoelectric conversion module body 13 by providing the heat transfer member 43 on the thermoelectric conversion module substrate 20a. In addition, by providing the heat transfer member 43 on the thermoelectric conversion module substrate 20a, the thermoelectric conversion module body 13 is allowed to be easily erected independently. Therefore, as shown in a thermoelectric conversion device 10d shown in FIG. 16, a simple configuration in which the heat dissipating fin 18 is not provided can be provided. In the thermoelectric conversion device 10d shown in FIG. 16, compared to the thermoelectric conversion device 10c shown in FIG. 15, since the heat dissipating fin 18 is not provided, a degree of freedom is high and the thermoelectric conversion device is applicable to heat sources of various shapes. For example, in the thermoelectric conversion device 10d shown in FIG. 16, the thermoelectric conversion module substrate 20a can be arranged on a curved surface and the bellows-like thermoelectric conversion module substrate 20a can be provided on a cylindrical pipe or the like.

In the thermoelectric conversion device 10d shown in FIG. 15 and the thermoelectric conversion device 10d shown in FIG. 16, the bellows-like thermoelectric conversion module substrate 20a is provided, but there is no limitation thereto. A plurality of thermoelectric conversion module bodies 13 shown in FIGS. 5 and 6 may be arranged. In this case, the heat transfer members 43 are arranged at both ends between the thermoelectric conversion module bodies 13 in the y direction. Thus, even in a case where a large number of thermoelectric conversion module bodies 13 are provided, the heat source temperature can be effectively supplied to the thermoelectric conversion module bodies 13. In addition, by providing the heat transfer members 43 at both ends between the thermoelectric conversion module bodies 13 in the y direction, the thermoelectric conversion module bodies 13 are allowed to be easily erected independently. In this case, as shown in FIG. 16, a simple configuration in which the heat dissipating fin 18 is not provided can be provided.

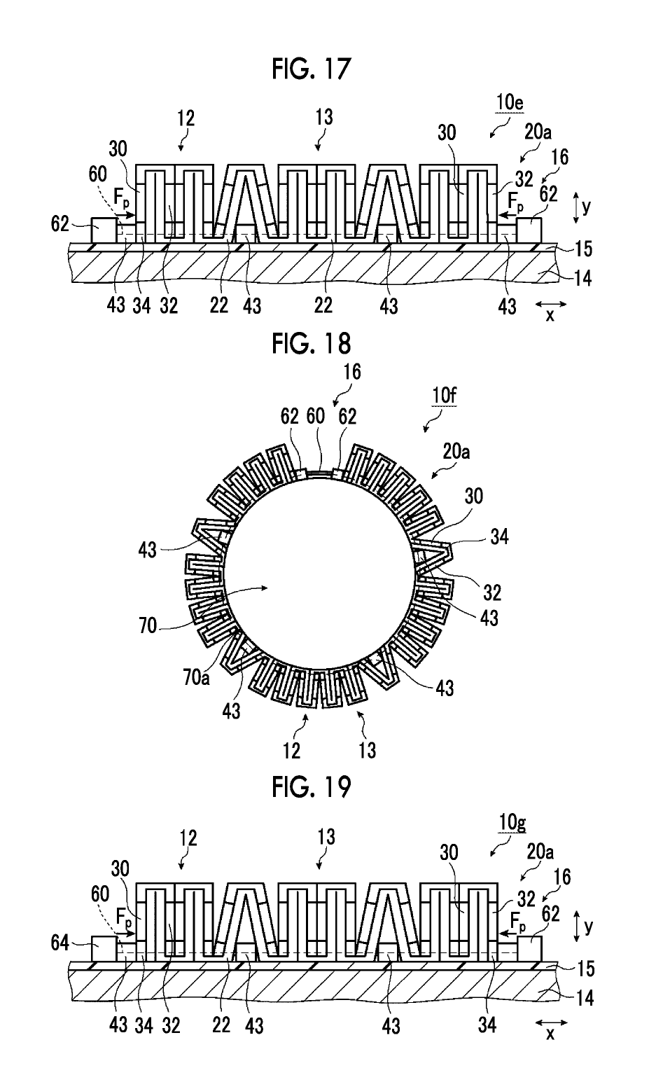

FIG. 17 is a schematic cross-sectional view showing a fourth example of the thermoelectric conversion device having the thermoelectric conversion module according to the embodiment of the present invention. In the thermoelectric conversion device 10e shown in FIG. 17, the same symbols are attached to the same structures as in the thermoelectric conversion device 10 shown in FIG. 1 and the thermoelectric conversion module substrate 20a shown in FIG. 7, and the detailed descriptions thereof are omitted.

The thermoelectric conversion device 10e shown in FIG. 17 is different from the thermoelectric conversion device 10 shown in FIG. 1 in that the thermoelectric conversion module body 13 is constituted of the bellows-like thermoelectric conversion module substrate 20a shown in FIG. 7 and the heat dissipating fin 18 is not provided. In the thermoelectric conversion module substrate 20a, for example, two heat transfer members 43 are provided on the bellows-like thermoelectric conversion module substrate 20a in the x direction and there are three partitioned regions. The heat transfer members 43 are included in the heat transfer portion 16.

In the thermoelectric conversion device 10e, the bellows-like thermoelectric conversion module substrate 20a is pressed in the arrangement direction, that is, in the x direction by a linear member 60 and an end portion fixing member 62 using the heat transfer members 43. Thus, the thermoelectric conversion module body 13 is allowed to be easily erected independently and a simple configuration in which the heat dissipating fin 18 is not provided can be provided. The linear member 60 and the end portion fixing member 62 constitute a pressing portion. The pressing portion has a simple and small configuration.

In the thermoelectric conversion device 10e shown in FIG. 17, the thermoelectric conversion module substrate 20a is pressed using the linear member 60, and the end portion fixing members 62 provided at both ends of the thermoelectric conversion module substrate 20a. As the linear member 60, for example, a metal or resin wire is used.

The end portion fixing member 62 is a block-shaped member and has a through hole (not shown) into which the linear member 60 is inserted on one surface thereof. In addition, a through hole (not shown) is provided in the end portion of the thermoelectric conversion module substrate 20a on the side close to the base 14, and a through hole (not shown) is also provided in the heat transfer member 43. The end portion fixing member 62 is not particularly limited in the configuration as long as the thermoelectric conversion module substrate 20a can be pressed in a use environment, and can be constituted of metal or resin.

The linear member 60 is inserted into the through hole of the thermoelectric conversion module substrate 20a and the through holes of the heat transfer members 43 and the end portion fixing members 62, the both surfaces of the thermoelectric conversion module substrate 20a are pressed by the two end portion fixing members 62, and the end portions of the linear member 60 are respectively fixed to the end portion fixing members 62 in a state in which the bellows-like thermoelectric conversion module substrate 20a is completely folded.

In the thermoelectric conversion device 10e, even in a case where the thermoelectric conversion module substrate 20a is long, as long as the heat transfer member 43 is provided, the heat source temperature can be effectively transferred to the thermoelectric conversion module body 13. Therefore, it is preferable that the linear member 60 and the end portion fixing member 62 are constituted of a high thermal conductive material having a thermal conductivity of 10 W/mK or higher. However, the members may not be constituted of a high thermal conductive material having a thermal conductivity of 10 W/mK or higher.

A method of fixing the end portion fixing member 62 and the linear member 60 is not particularly limited and for example, various known fixing methods such as a method of filling the through hole of the end portion fixing member 62 into which the linear member 60 is inserted with an adhesive for fixing, a method of providing a knot formed by knotting the end portions of the linear member 60 inserted into the through hole of the end portion fixing member 62 to fix the end portion fixing member 62, and the like can be appropriately used.

In addition, two end portion fixing members 62 are used but there is no limitation thereto. One end portion fixing member 62 may be provided. In this case, in a state in which the linear member 60 is inserted into the end portion fixing member, one end portion of the linear member is fixed to the heat transfer member 43, one surface of the thermoelectric conversion module substrate 20a is pressed by one end portion fixing member 62, and in a state in which the bellows-like thermoelectric conversion module substrate 20a is completely folded, the other end portion of the linear member 60 is fixed to the end portion fixing member 62.

The example in which the bellows-like thermoelectric conversion module substrate 20a is arranged on the base 14 having a flat surface in the thermoelectric conversion device 10e shown in FIG. 17 is described but there is no limitation thereto. For example, the bellows-like thermoelectric conversion module substrate 20a can be arranged on a surface 70a of a cylindrical pipe 70 as in a thermoelectric conversion device 10f shown in FIG. 18.

In the thermoelectric conversion device 10f shown in FIG. 18, the same symbols are attached to the same structures as in the thermoelectric conversion device 10e shown in FIG. 17, and the detailed descriptions thereof are omitted.

In the thermoelectric conversion device 10f, the bellows-like thermoelectric conversion module substrate 20a is deformed along the surface 70a of the pipe 70 in a state in contact with the surface 70a, and both end portions of the linear member 60 are connected and fixed. Then, the thermoelectric conversion module substrate 20a can be arranged along the surface 70a of the pipe 70. Thus, the temperature of the pipe 70 and a fluid flowing in the pipe 70 can be used as a heat source, and for example, waste heat of plant wastewater, plant combustion exhaust gas, exhaust steam, or the like can be used as a heat source.

In this case, in the thermoelectric conversion device 10f shown in FIG. 18, the thermoelectric conversion module substrate 20a can be arranged on the surface 70a of the pipe 70 along a vertical drag, and the heat source temperature can be effectively transferred to the thermoelectric conversion module body 13.

In a thermoelectric conversion device 10g shown in FIG. 19, instead of using the end portion fixing member 62, a magnetic force fixing member 64 may be used. In the thermoelectric conversion device 10g shown in FIG. 19, the same symbols are attached to the same structures as in the thermoelectric conversion device 10e shown in FIG. 17, and the detailed descriptions thereof are omitted.

In the thermoelectric conversion device 10g, a through hole (not shown) into which the linear member 60 is inserted is provided in the magnetic force fixing member 64 as in the end portion fixing member 62.

By the magnetic force working between two magnetic force fixing members 64, the thermoelectric conversion module substrate 20a is pressed in the arrangement direction, that is, in the x direction. Thus, the thermoelectric conversion module substrate 20a is allowed to be erected independently and a simple configuration in which the heat dissipating fin 18 is not provided can be provided.

In this case, as long as the thermally conductive sheet 15 sticks to a magnet, the magnetic force fixing member 64 is fixed to the base 14 due to a magnetic force. The use of the magnetic force fixing member 64 enables the thermoelectric conversion module substrate 20a to be easily attached to and detached, and the pressing of the thermoelectric conversion module substrate 20a can be realized by a simple and small configuration. At this time, it is not necessary to fix the magnetic force fixing member 64 to the thermally conductive sheet 15 using an adhesive or the like. In a case where the thermally conductive sheet 15 does not stick to a magnet, the magnetic force fixing member 64 is fixed to the thermally conductive sheet 15 using an adhesive or the like.

Further, as long as the thermoelectric conversion module substrate 20a is pressed by only the magnetic force fixing member 64 and the thermoelectric conversion module body 13 is allowed to be erected independently, the linear member 60 is not necessarily required.

The magnetic force fixing member 64 is not particularly limited in the configuration as long as the thermoelectric conversion module substrate 20a can be pressed by a magnetic force in a use environment, and for example, the magnetic force fixing member may be constituted of an iron oxide magnet.

In the thermoelectric conversion device 10g, even in a case where the thermoelectric conversion module substrate 20a is long, as long as the heat transfer member 43 is provided, the heat source temperature can be effectively transferred to the thermoelectric conversion module body 13. Therefore, it is preferable that the magnetic force fixing member 64 is constituted of a high thermal conductive material having a thermal conductivity of 10 W/mK or higher. However, the member may not be constituted of a high thermal conductive material having a thermal conductivity of 10 W/mK or higher.

In addition, two magnetic force fixing members 64 are used but there is no limitation thereto. One magnetic force fixing member 64 may be provided. In this case, in a state in which the linear member 60 is inserted into the magnetic force fixing member, one end portion of the linear member is fixed to the heat transfer member 43, one surface of the thermoelectric conversion module substrate 20a is pressed by one magnetic force fixing member 64. In a state in which the bellows-like thermoelectric conversion module substrate 20a is completely folded, the magnetic force fixing member 64 is fixed to the thermally conductive sheet 15 by a magnetic force and the other end portion of the linear member 60 is fixed to the magnetic force fixing member 64.

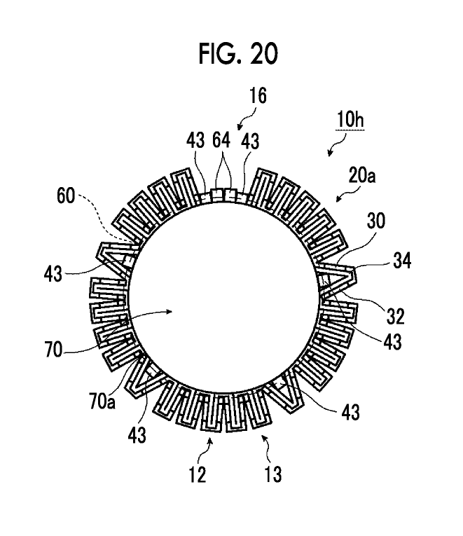

In a case of using the magnetic force fixing member 64, as in a thermoelectric conversion device 10h shown in FIG. 20, the thermoelectric conversion module substrate can be arranged on the surface 70a of the cylindrical pipe 70.

In the thermoelectric conversion device 10h shown in FIG. 20, the same symbols are attached to the same structures as in the thermoelectric conversion device 10g shown in FIG. 19, and the detailed descriptions thereof are omitted.

In the thermoelectric conversion device 10h, in a state in which the thermoelectric conversion module substrate 20a is in contact with the surface 70a of the pipe 70, thermoelectric conversion module substrate is deformed along the surface 70a, and the magnetic force fixing members 64 are fixed by causing the members to stick to each other by the magnetic force. Thus, the thermoelectric conversion module substrate 20a can be arranged along the surface 70a of the pipe 70. Thus, as described above, the temperature of the pipe 70 and a fluid flowing in the pipe 70 can be used as a heat source. In this case, in the thermoelectric conversion device 10h, the thermoelectric conversion module substrate 20a can be arranged on the surface 70a of the pipe 70 along a vertical drag and the heat source temperature can be effectively transferred to the thermoelectric conversion module body 13.

In a case where the pipe 70 sticks to a magnet, the use of the magnetic force fixing member 64 makes it possible to fix the thermoelectric conversion module substrate 20a to the pipe 70 without using an adhesive or the like, and the thermoelectric conversion module substrate 20a can be easily attached or detached.

In the thermoelectric conversion device 10e shown in FIG. 17 and the thermoelectric conversion device 10g shown in FIG. 19, the bellows-like thermoelectric conversion module substrate 20a is provided but there is no limitation thereto. A plurality of thermoelectric conversion module bodies 13 shown in FIGS. 5 and 6 may be arranged. In this case, the heat transfer members 43 are arranged at both ends between the thermoelectric conversion module bodies 13 in the y direction. Thus, even in a case where a large number of thermoelectric conversion module bodies 13 are provided, the heat source temperature can be effectively supplied to the thermoelectric conversion module bodies 13. In addition, by providing the heat transfer members 43 at both ends between the thermoelectric conversion module bodies 13 in the y direction, the thermoelectric conversion module bodies 13 are allowed to be easily erected independently. In this case, as shown in FIGS. 17 and 18, a simple configuration in which the heat dissipating fin 18 is not provided can be provided.

Hereinafter, the constitutional members of the above-described thermoelectric conversion modules 12 and 12a will be described in more detail.

Since the thermoelectric conversion module 12 and the thermoelectric conversion module 12a basically have the same configuration, the thermoelectric conversion module 12 will be described representatively.

The insulating substrate 22 has the P-type thermoelectric conversion element 24, the N-type thermoelectric conversion element 26 formed thereon and the like. The insulating substrate functions as a support for the P-type thermoelectric conversion element 24 and the N-type thermoelectric conversion element 26. Since voltage is generated in the thermoelectric conversion module 12, the insulating substrate 22 is required to have electrically insulating properties, and a substrate having electrically insulating properties is used for the insulating substrate 22. The electrically insulating properties required for the insulating substrate 22 are to prevent a short circuit or the like due to the voltage generated in the thermoelectric conversion module 12. Regarding the insulating substrate 22, a substrate is appropriately selected according to the voltage generated in the thermoelectric conversion module 12.

The insulating substrate 22 has flexibility and for example, a plastic substrate is used. For the plastic substrate, a plastic film can be used.

Specific examples of the plastic film that can be used include films or sheet-like materials or plate-like materials of polyester resins such as polyethylene terephthalate, polyethylene isophthalate, polyethylene naphthalate, polybutylene terephthalate, poly(1,4-cyclohexylene dimethylene terephthalate), and polyethylene-2,6-naphthalenedicarboxylate, resins such as polyimide, polycarbonate, polypropylene, polyethersulfone, cycloolefin polymer, and polyether ether ketone (PEEK), triacetyl cellulose (TAC), glass epoxy, and liquid crystal polyester.

Among these, from the viewpoint of thermal conductivity, heat resistance, solvent resistance, ease of availability, and economy, films of polyimide, polyethylene terephthalate, polyethylene naphthalate, and the like are suitably used for the insulating substrate 22.

Hereinafter, the P-type thermoelectric conversion layer 30 and the N-type thermoelectric conversion layer 32 will be described.

As the thermoelectric conversion material constituting the P-type thermoelectric conversion layer 30 and the N-type thermoelectric conversion layer 32, for example, nickel or a nickel alloy may be used.

As the nickel alloy, various nickel alloys that generate power by causing a temperature difference can be used. Specific examples thereof include nickel alloys mixed with one or two or more of vanadium, chromium, silicon, aluminum, titanium, molybdenum, manganese, zinc, tin, copper, cobalt, iron, magnesium, and zirconium.

In a case where nickel or a nickel alloy is used for the P-type thermoelectric conversion layer 30 and the N-type thermoelectric conversion layer 32, the nickel content in the P-type thermoelectric conversion layer 30 and the N-type thermoelectric conversion layer 32 is preferably 90% by atom or more and more preferably 95% by atom or more, and the thermoelectric conversion layers are particularly preferably formed of nickel. The P-type thermoelectric conversion layer 30 and the N-type thermoelectric conversion layer 32 formed of nickel include inevitable impurities.

As the thermoelectric conversion material for the P-type thermoelectric conversion layer 30, chromel having Ni and Cr as main components is typically used. As the thermoelectric material for the N-type thermoelectric conversion layer 32, constantan having Cu and Ni as main components is typically used.

In addition, in a case where nickel or a nickel alloy is used for the P-type thermoelectric conversion layer 30 and the N-type thermoelectric conversion layer 32 and also nickel or a nickel alloy is used for an electrode, the P-type thermoelectric conversion layer 30, the N-type thermoelectric conversion layer 32, and the connection electrode 34 may be integrally formed.

As other thermoelectric materials for the P-type thermoelectric conversion layer 30 and the N-type thermoelectric conversion layer 32, for example, the following materials may be used. Incidentally, the components in parentheses indicate the material composition. Examples of the materials include BiTe-based materials (BiTe, SbTe, BiSe and compounds thereof), PbTe-based materials (PbTe, SnTe, AgSbTe, GeTe and compounds thereof), Si—Ge-based materials (Si, Ge, SiGe), silicide-based materials (FeSi, MnSi, CrSi), skutterudite-based materials (compounds represented by MX₃ or RM₄X₁₂, where M equals Co, Rh, or Ir, X equals As, P, or Sb, and R equals La, Yb, or Ce), transition metal oxides (NaCoO, CaCoO, ZnInO, SrTiO, BiSrCoO, PbSrCoO, CaBiCoO, BaBiCoO), zinc antimony based compounds (ZnSb), boron compounds (CeB, BaB, SrB, CaB, MgB, VB, NiB, CuB, LiB), cluster solids (B cluster, Si cluster, C cluster, AlRe, AlReSi), and zinc oxides (ZnO). In addition, the film formation method is arbitrary and a film formation method such as a sputtering method, a vapor deposition method, a CVD method, a plating method, or an aerosol deposition method can be used.

In addition, for the thermoelectric conversion material used for the P-type thermoelectric conversion layer 30 and the N-type thermoelectric conversion layer 32, various configurations using known thermoelectric conversion materials including an organic material as a material that can form a film by coating or printing and can be made into paste can be used.

Specific examples of the thermoelectric conversion material from which the P-type thermoelectric conversion layer 30 and the N-type thermoelectric conversion layer 32 as described above can be obtained include an organic thermoelectric conversion material such as a conductive polymer or a conductive nanocarbon material may be used.

Examples of the conductive polymer include a polymer compound having a conjugated molecular structure (conjugated polymer). Specific examples thereof include known n-conjugated polymers such as polyaniline, polyphenylene vinylene, polypyrrole, polythiophene, polyfluorene, acetylene, and polyphenylene. Particularly, polydioxythiophene can be suitably used.

Specific examples of the conductive nanocarbon material include carbon nanotubes (hereinafter, also referred to as CNTs), carbon nanofiber, graphite, graphene, and carbon nanoparticles. These may be used singly or in combination of two or more thereof. Among these, from the viewpoint of further improving thermoelectric properties, CNT is preferably used.

CNT is categorized into single layer CNT of one carbon film (graphene sheet) wound in the form of a cylinder, double layer CNT of two graphene sheets wound in the form of concentric circles, and multilayer CNT of a plurality of graphene sheets wound in the form of concentric circles. In the present invention, each of the single layer CNT, the double layer CNT, and the multilayer CNT may be used singly, or two or more thereof may be used in combination. Particularly, the single layer CNT and the double layer CNT excellent in conductivity and semiconductor characteristics are preferably used, and the single layer CNT is more preferably used.

The single layer CNT may be semiconductive or metallic. Furthermore, semiconductive CNT and metallic CNT may be used in combination. In a case where both of the semiconductive CNT and the metallic CNT are used, a content ratio between the CNTs in a composition can be appropriately adjusted according to the use of the composition. In addition, CNT may contain a metal or the like, and CNT containing fullerene molecules and the like may be used.

An average length of CNT is not particularly limited and can be appropriately selected according to the use of the composition. Specifically, from the viewpoint of ease of manufacturing, film formability, conductivity, and the like, the average length of CNT is preferably 0.01 to 2,000 μm, more preferably 0.1 to 1,000 μm, and particularly preferably 1 to 1,000 μm, though the average length also depends on an inter-electrode distance.

A diameter of CNT is not particularly limited. From the viewpoint of durability, transparency, film formability, conductivity, and the like, the diameter is preferably 0.4 to 100 nm, more preferably 50 nm or less, and particularly preferably 15 nm or less.

Particularly, in a case where the single layer CNT is used, the diameter is preferably 0.5 to 2.2 nm, more preferably 1.0 to 2.2 nm, and particularly preferably 1.5 to 2.0 nm.

The CNT contained in the obtained conductive composition contains defective CNT in some cases. Because the defectiveness of the CNT deteriorates the conductivity of the composition, it is preferable to reduce the amount of the defective CNT. The amount of defectiveness of the CNT in the composition can be estimated by a G/D ratio between a G band and a D band in a Raman spectrum. In a case where the G/D ratio is high, the composition can be assumed to be a CNT material with a small amount of defectiveness. The G/D ratio of the composition is preferably 10 or higher and more preferably 30 or higher.

In addition, modified or treated CNT can also be used. Examples of the modification or treatment method include a method of incorporating a ferrocene derivative or nitrogen-substituted fullerene (azafullerene) into CNT, a method of doping CNT with an alkali metal (potassium or the like) or a metallic element (indium or the like) by an ion doping method, and a method of heating CNT in a vacuum.

In a case where CNT is used, in addition to the single layer CNT or the multilayer CNT, nanocarbons such as carbon nanohorns, carbon nanocoils, carbon nanobeads, graphite, graphene, amorphous carbon, and the like may be contained in the composition.

In a case where CNT is used in the P-type thermoelectric conversion layer or the N-type thermoelectric conversion layer, it is preferable that CNT includes a P-type dopant or an N-type dopant.

(P-Type Dopant)

Examples of the P-type dopant include halogen (iodine, bromine, or the like), Lewis acid (PF₅, AsF₅, or the like), protonic acid (hydrochloric acid, sulfuric acid, or the like), transition metal halide (FeCl₃, SnCl₄, or the like), a metal oxide (molybdenum oxide, vanadium oxide, or the like), and an organic electron-accepting material. Examples of the organic electron-accepting material suitably include a tetracyanoquinodimethane (TCNQ) derivative such as 2,3,5,6-tetrafluoro-7,7,8,8-tetracyanoquinodimethane, 2,5-dimethyl-7,7,8,8-tetracyanoquinodimethane, 2-fluoro-7,7,8,8-tetracyanoquinodimethane, or 2,5-difluoro-7,7,8,8-tetracyanoquinodimethane, a benzoquinone derivative such as 2,3-dichloro-5,6-dicyano-p-benzoquinone or tetrafluoro-1,4-benzoquinone, 5,8H-5,8-bis(dicyanomethylene)quinoxaline, dipyrazino[2,3-f:2′,3′-h]quinoxaline-2,3,6,7,10,11-hexacarbonitrile, and the like.

Among these, from viewpoint of the stability of the materials, the compatibility with CNT, and the like, organic electron-accepting materials such as a tetracyanoquinodimethane (TCNQ) derivative or a benzoquinone derivative are suitably exemplified.

The P-type dopant and the N-type dopant may be used singly or in combination of two or more thereof.

(N-Type Dopant)

As the N-type dopant, known material such as (1) alkali metals such as sodium and potassium, (2) phosphines such as triphenylphosphine and ethylenebis(diphenylphosphine), (3) polymers such as polyvinyl pyrrolidone and polyethylene imine, and the like can be used. In addition, for examples, polyethylene glycol type higher alcohol ethylene oxide adducts, ethylene oxide adducts of phenol, naphthol or the like, fatty acid ethylene oxide adducts, polyhydric alcohol fatty acid ester ethylene oxide adducts, higher alkylamine ethylene oxide adducts, fatty acid amide ethylene oxide adducts, ethylene oxide adducts of fat, polypropylene glycol ethylene oxide adducts, dimethylsiloxane-ethylene oxide block copolymers, dimethylsiloxane-(propylene oxide-ethylene oxide) block copolymers, fatty acid esters of polyhydric alcohol type glycerol, fatty acid esters of pentaerythritol, fatty acid esters of sorbitol and sorbitan, fatty acid esters of sucrose, alkyl ethers of polyhydric alcohols and fatty acid amides of alkanolamines. Further, acetylene glycol based and acetylene alcohol-based oxyethylene adducts, and fluorine-based and silicon-based surfactants can be also used. As the N-type dopant, a commercially available product can be used.

In the thermoelectric conversion element, the thermoelectric conversion layer obtained by dispersing the aforementioned thermoelectric conversion material in a resin material (binder) is suitably used.

Among these, the thermoelectric conversion layer obtained by dispersing a conductive nanocarbon material in a resin material is more suitably exemplified. Especially, the thermoelectric conversion layer obtained by dispersing CNT in a resin material is particularly suitably exemplified because this makes it possible to obtain high conductivity and the like.

As the resin material, various known nonconductive resin materials (polymers) can be used.

Specifically, it is possible to use various known resin materials such as a vinyl compound, a (meth)acrylate compound, a carbonate compound, an ester compound, an epoxy compound, a siloxane compound, and gelatin.

More specifically, examples of the vinyl compound include polystyrene, polyvinyl naphthalene, polyvinyl acetate, polyvinyl phenol, and polyvinyl butyral. Examples of the (meth)acrylate compound include polymethyl (meth)acrylate, polyethyl (meth)acrylate, polyphenoxy(poly)ethylene glycol (meth)acrylate, and polybenzyl (meth)acrylate. Examples of the carbonate compound include bisphenol Z-type polycarbonate, and bisphenol C-type polycarbonate. Examples of the ester compound include amorphous polyester.

Polystyrene, polyvinyl butyral, a (meth)acrylate compound, a carbonate compound, and an ester compound are preferable, and polyvinyl butyral, polyphenoxy(poly)ethylene glycol (meth)acrylate, polybenzyl (meth)acrylate, and amorphous polyester are more preferable.

In the thermoelectric conversion layer obtained by dispersing a thermoelectric conversion material in a resin material, a quantitative ratio between the resin material and the thermoelectric conversion material may be appropriately set according to the material used, the thermoelectric conversion efficiency required, the viscosity or solid content concentration of a solution exerting an influence on printing, and the like.

As another configuration of the thermoelectric conversion layer in the thermoelectric conversion element, a thermoelectric conversion layer mainly constituted of CNT and a surfactant is also suitably used.

By constituting the thermoelectric conversion layer of CNT and a surfactant, the thermoelectric conversion layer can be formed using a coating composition to which a surfactant is added. Therefore, the thermoelectric conversion layer can be formed using a coating composition in which CNT is smoothly dispersed. As a result, by a thermoelectric conversion layer including a large amount of long and less defective CNT, excellent thermoelectric conversion performance is obtained.

As the surfactant, known surfactants can be used as long as the surfactants function to disperse CNT. More specifically, various surfactants can be used as the surfactant as long as surfactants dissolve in water, a polar solvent, or a mixture of water and a polar solvent and have a group adsorbing CNT.

Accordingly, the surfactant may be ionic or nonionic. Furthermore, the ionic surfactant may be any of cationic, anionic, and amphoteric surfactants.

Examples of the anionic surfactant include an aromatic sulfonic acid-based surfactant such as alkylbenzene sulfonate like dodecylbenzene sulfonate or dodecylphenylether sulfonate, a monosoap-based anionic surfactant, an ether sulfate-based surfactant, a phosphate-based surfactant, a carboxylic acid-based surfactant such as sodium deoxycholate or sodium cholate, and a water-soluble polymer such as carboxymethyl cellulose and a salt thereof (sodium salt, ammonium salt, or the like), a polystyrene sulfonate ammonium salt, or a polystyrene sulfonate sodium salt.

Examples of the cationic surfactant include an alkylamine salt and a quaternary ammonium salt. Examples of the amphoteric surfactant include an alkyl betaine-based surfactant, and an amine oxide-based surfactant.

Further, examples of the nonionic surfactant include a sugar ester-based surfactant such as sorbitan fatty acid ester, a fatty acid ester-based surfactant such as polyoxyethylene resin acid ester, and an ether-based surfactant such as polyoxyethylene alkyl ether.

Among these, an ionic surfactant is preferably used, and cholate or deoxycholate is particularly suitably used.

In the thermoelectric conversion layer, a mass ratio of surfactant/CNT is preferably 5 or less, and more preferably 3 or less.

It is preferable that the mass ratio of surfactant/CNT is 5 or less from the viewpoint that a higher thermoelectric conversion performance or the like is obtained.

If necessary, the thermoelectric conversion layer formed of an organic material may contain an inorganic material such as SiO₂, TiO₂, Al₂O₃, or ZrO₂.

In a case where the thermoelectric conversion layer contains an inorganic material, a content of the inorganic material is preferably 20% by mass or less, and more preferably 10% by mass or less.

In the thermoelectric conversion element, a thickness of the thermoelectric conversion layer, a size of the thermoelectric conversion layer in a plane direction, a proportion of an area of the thermoelectric conversion layer with respect to the insulating substrate along the plane direction, and the like may be appropriately set according to the material forming the thermoelectric conversion layer, the size of the thermoelectric conversion element, and the like.

Next, a method of forming the thermoelectric conversion layer will be described.

The prepared coating composition which becomes the thermoelectric conversion layer is patterned and applied according to a thermoelectric conversion layer to be formed. The application of the coating composition may be performed by a known method such as a method using a mask or a printing method.

After the coating composition is applied, the coating composition is dried by a method according to the resin material, thereby forming the thermoelectric conversion layer. If necessary, after the coating composition is dried, the coating composition (resin material) may be cured by being irradiated with ultraviolet rays or the like.

Alternatively, the prepared coating composition which becomes the thermoelectric conversion layer is applied to the entire surface of the insulating substrate and dried, and then the thermoelectric conversion layer may be formed as a pattern by etching or the like.

In order to form the thermoelectric conversion layers on both surfaces of the insulating substrate, the layer may be formed on one surface by printing by any of the above-described methods and then the layer may be formed on the rear surface in the same manner.

In a case of the thermoelectric conversion module substrate 20, in the configuration shown in FIG. 2, the P-type thermoelectric conversion layer 30 is formed on the surface 22a of the insulating substrate 22 as a pattern and then the N-type thermoelectric conversion layer 32 is formed as a pattern. The pattern formation order of the P-type thermoelectric conversion layer 30 and the N-type thermoelectric conversion layer 32 may be reversed.

In the configuration shown in FIG. 3, the P-type thermoelectric conversion layer 30 is formed on the surface 22a of the thermoelectric conversion module substrate 20 as a pattern and in the configuration shown in FIG. 4, the N-type thermoelectric conversion layer 32 is formed on the surface 22a of the thermoelectric conversion module substrate 20 as a pattern.

Since the insulating substrate 22 has flexibility, the P-type thermoelectric conversion element 24 and the N-type thermoelectric conversion element 26 can be produced by, for example, a roll-to-roll method.

Next, in a case where the thermoelectric conversion layer is formed by a coating composition prepared such a manner that CNT and a surfactant are added to water and dispersed (dissolved), it is preferable to form the thermoelectric conversion layer by forming the thermoelectric conversion layer with the coating composition, then immersing the thermoelectric conversion layer in a solvent for dissolving the surfactant or washing the thermoelectric conversion layer with a solvent for dissolving the surfactant, and drying the thermoelectric conversion layer. Thus, it is possible to form the thermoelectric conversion layer having a very small mass ratio of surfactant/CNT by removing the surfactant from the thermoelectric conversion layer and more preferably not containing the surfactant. The thermoelectric conversion layer is preferably formed as a pattern by printing.

As the printing method, various known printing methods such as screen printing and metal mask printing can be used. In a case where the thermoelectric conversion layer is formed as a pattern by using a coating composition containing CNT, it is more preferable to use metal mask printing. The printing conditions may be appropriately set according to the physical properties (solid content concentration, viscosity, and viscoelastic properties) of the coating composition used, the opening size of a printing plate, the number of openings, the opening shape, a printing area, and the like. Specifically, an attack angle of a squeegee is preferably 50° or less, more preferably 40° or less, and particularly preferably 30° or less. As the squeegee, it is possible to use an obliquely polished squeegee, a sword squeegee, a square squeegee, a flat squeegee, a metal squeegee, and the like. The squeegee direction (printing direction) is preferably the same as the direction in which the thermoelectric conversion elements are connected to each other in series. A clearance is preferably 0.1 to 3.0 mm, and more preferably 0.5 to 2.0 mm. The printing can be performed at a printing pressure of 0.1 to 0.5 MPa in a squeegee indentation amount of 0.1 to 3 mm. By performing printing under such conditions, a CNT-containing thermoelectric conversion layer pattern having a film thickness of 1 μm or more can be suitably formed.

The connection electrodes 34 are formed at both ends of the pattern of the thermoelectric conversion material layer in the temperature difference direction and electrically connect the plurality of thermoelectric conversion material patterns. The connection electrode 34 is not particularly limited as long as the connection electrode 34 is formed of a conductive material, and any material may be used. As the material constituting the connection electrode 34, metal materials such as Al, Cu, Ag, Au, Pt, Cr, Ni, and solder are preferable. From the viewpoint of conductivity or the like, the connection electrode 34 is preferably constituted of copper. In addition, the connection electrode 34 may be constituted of a copper alloy.

The thermoelectric conversion modules 12 and 12a can be used for the thermoelectric conversion device 10 shown in FIG. 1, the thermoelectric conversion device 10a shown in FIG. 13, the thermoelectric conversion device 10b shown in FIG. 14, the thermoelectric conversion device 10c shown in FIG. 15, the thermoelectric conversion device 10d shown in FIG. 16, the thermoelectric conversion device 10e shown in FIG. 17, the thermoelectric conversion device 10f shown in FIG. 18, the thermoelectric conversion device 10g shown in FIG. 19, and the thermoelectric conversion device 10h shown in FIG. 20 but there is no limitation thereto.

In the thermoelectric conversion modules 12 and 12a, by bringing the end portion of the thermoelectric conversion module body 13 on the side close to one connection electrode 34 into contact with a member formed of a known high thermal conductive material such as stainless steel, copper, aluminum, or an aluminum alloy and bringing the member to a high temperature portion, a heat flow is formed from the end portion brought into contact with the high temperature portion to the opposite end portion direction of the thermoelectric conversion module body 13 to generate power. By bringing the member formed of a known high thermal conductive material such as stainless steel, copper, aluminum, or an aluminum alloy into contact with the opposite end portion of the thermoelectric conversion module body 13 and further attaching a heat dissipating fin to the member, a temperature difference between both ends of the insulating substrate can be increased and the power generation amount can be improved.

In a case of bonding the thermoelectric conversion module to the heat source to generate power, as described above, the thermally conductive sheet, the thermally conductive adhesive sheet and the thermally conductive adhesive may be used.

The thermally conductive sheet, the thermally conductive adhesive sheet and the thermally conductive adhesive used by being bonded to a heating side or a cooling side of the thermoelectric conversion module are not particularly limited. Accordingly, commercially available thermally conductive adhesive sheets or thermally conductive adhesives can be used. As the thermally conductive adhesive sheet, for example, it is possible to use TC-50TXS2 manufactured by Shin-Etsu Silicone, a hyper soft heat dissipating material 5580H manufactured by Sumitomo 3M, Ltd., BFG20A manufactured by Denka Company Limited., TR5912F manufactured by NITTO DENKO CORPORATION, and the like. From the viewpoint of heat resistance, a thermally conductive adhesive sheet constituted of a silicone-based pressure sensitive adhesive is preferable. As the thermally conductive adhesive, for example, it is possible to use SCOTCH-WELD EW2070 manufactured by 3M, TA-01 manufactured by Ainex Co., Ltd., TCA-4105, TCA-4210, and HY-910 manufactured by Shiima Electronics, Inc., SST2-RSMZ, SST2-RSCSZ, R3CSZ, and R3MZ manufactured by SATSUMASOKEN CO., LTD., and the like.

The use of the thermally conductive adhesive sheet or the thermally conductive adhesive brings about an effect of increasing a surface temperature of the heating side of the thermoelectric conversion module by improving the adhesiveness with respect to the heat source, an effect of being able to reduce a surface temperature of the cooling side of the thermoelectric conversion module by improving the cooling efficiency, and the like, and accordingly, the power generation amount can be improved.

Further, on the surface of the cooling side of the thermoelectric conversion module, a heat dissipating fin (heat sink) or a heat dissipating sheet consisting of a known material such as stainless steel, copper, aluminum or aluminum alloy may be provided. It is preferable to use the heat dissipating fin, since a low temperature side of the thermoelectric conversion module can be more suitably cooled, a large temperature difference is caused between the heat source side and the cooling side, and the thermoelectric conversion efficiency is further improved.

As the heat dissipating fin, it is possible to use various known fins such as T-Wing manufactured by TAIYO WIRE CLOTH CO., LTD, FLEXCOOL manufactured by SHIGYOSOZO KENKYUSHO, a corrugated fin, an offset fin, a waving fin, a slit fin, and a folding fin. Particularly, it is preferable to use a folding fin having a fin height.

The heat dissipating fin preferably has a fin height of 10 to 56 mm, a fin pitch of 2 to 10 mm, and a plate thickness of 0.1 to 0.5 mm. The fin height is more preferably 25 mm or more from the viewpoint that the heat dissipating characteristics are improved, the thermoelectric conversion module can be cooled, and hence the power generation amount is improved. It is preferable to use a heat dissipating fin made of aluminum having a plate thickness of 0.1 to 0.3 mm from the viewpoint of obtaining a fin having high flexibility, lightweight, and the like.

In addition, as the heat dissipating sheet, it is possible to use known heat dissipating sheets such as a PSG graphite sheet manufactured by Panasonic Corporation, COOL STAFF manufactured by Oki Electric Cable Co., Ltd., and CERAC ac manufactured by CERAMISSION CO., LTD.

The example in which the thermoelectric conversion module is used in the thermoelectric conversion device using a temperature difference has been described above, but there is no limitation thereto. For example, the thermoelectric conversion module can be used as cooling device which performs cooling by energization. Even in this case, since a thermally conductive portion is provided, the cooling efficiency can be increased.

The present invention is basically constituted as described above. While the thermoelectric conversion module of the present invention has been described above in detail, the present invention is not limited to the above embodiments, and various improvements and modifications may of course be made without departing from the spirit of the present invention.

### First Example

Hereinafter, the features of the present invention will be further specifically described with reference to the following examples. The materials, reagents, used amounts, amounts of substances, ratios, treatment contents, treatment procedures, and the like shown in the following examples can be appropriately changed without departing from the scope of the present invention. Therefore, the following specific examples are to be considered in all respects as illustrative and not restrictive.

In a first example, basically, the configuration of the thermoelectric conversion device 10 shown in FIG. 1 was used.

A thermoelectric conversion module body 13 in which fifty thermoelectric conversion module substrates 20 shown in FIG. 2 were overlapped such that the direction of the insulating substrate 22 and the direction of the connection electrode 34 were aligned and the thermoelectric conversion elements faced the rear surface 22b of the insulating substrate 22 to avoid direct contact between the thermoelectric conversion elements was used.

The heat transfer portion 16 having the configuration shown in FIG. 8 was provided in the thermoelectric conversion module body 13 and the thermoelectric conversion module body 13 was pressed with the frame portion 42 by rotating the screw 44 of the outer frame 40. Thus, a normal stress was applied to the thermoelectric conversion module substrate 20. Super low pressure PRESCALE (two-sheet type super low pressure (LLW), manufactured by Fujifilm Corporation) and PRESCALE MAT were overlapped and sandwiched between the connection electrode at the center portion of the thermoelectric conversion module body 13 in the x direction and the rear surface of the insulating substrate, and the amount of rotation of the screw 44 was adjusted such that the normal stress applied to the surface of the connection electrode reached a preset stress value. At a normal pressure of lower than 0.01 MPa described later, in the above-described measurement method using super low pressure PRESCALE (two-sheet type super low pressure (LLW), manufactured by Fujifilm Corporation) and PRESCALE MAT, super low pressure PRESCALE did not react and did not develop color.

The frame portion 42 was constituted of an aluminum alloy A5052 (Japanese Industrial Standards (JIS) H4000:2014) having a thermal conductivity of 236 W/mK. In addition, for the frame portion 42, a flat plate having a width of 10 mm and a thickness of 3 mm was used. In the frame portion 42, the recessed portion 42d sized so as to surround the thermoelectric conversion module body 13 having a size of vertical 10 mm and horizontal 120 mm, and a thickness of 1.25 mm (substrate thickness: 25 μm×50 sheets) was formed. For the outer frame 40, a flat plate having a width of 10 mm and a thickness of 3 mm was used and was arranged so as to surround the periphery of the frame portion 42.

The vertical of the thermoelectric conversion module body 13 corresponds to the y direction (refer to FIG. 1), the thickness corresponds to the x direction (refer to FIG. 1), and the horizontal corresponds to a direction orthogonal to the y direction and the x direction. Hereinafter, unless otherwise specified, the vertical and horizontal correspond to the above-described directions.

In the thermoelectric conversion module substrate 20, the followings were used.

For the insulating substrate 22, a polyimide film having a size of vertical 10 mm and horizontal 120 mm, and a thickness of 25 μm was used.

For the connection electrode 34, a conductive film having a width of 2.5 mm and a thickness of 300 nm produced by a sputtering method using aluminum was used. The width of the connection electrode 34 is the above-described horizontal length.

In the P-type thermoelectric conversion layer, the followings were used.

[Preparation of Coating Composition which Becomes P-Type Thermoelectric Conversion Layer]

EC (manufactured by Meijo Nano Carbon., average length of CNT: 1 μm or more) as single layer CNT and sodium deoxycholate were added to 20 ml of water such that a mass ratio of CNT/sodium deoxycholate became 25/75, thereby preparing a solution.

This solution was mixed for 7 minutes by using a mechanical homogenizer to obtain a premix.

By using a thin film spin system high speed mixer, a dispersion treatment was performed on the obtained premix for 2 minutes at a circumferential speed of 10 m/sec and then for 5 minutes at a circumferential speed of 40 m/sec in a thermostatic bath with a temperature of 10° C. by a high speed spinning thin film dispersion method, thereby preparing a coating composition which becomes the thermoelectric conversion layer.

The Seebeck coefficient of the P-type thermoelectric conversion material was evaluated using ZEM-3 manufactured by Advance Riko Corporation. As a result, the Seebeck coefficient was 50 μV/K.

In the N-type thermoelectric conversion layer, the follows were used.

[Preparation of Coating Composition which Becomes N-Type Thermoelectric Conversion Layer]

EC (manufactured by Meijo Nano Carbon., average length of CNT: 1 μm or more) as single layer CNT and EMULGEN 350 (manufactured by Kao Corporation) were added to 20 ml of water such that a mass ratio of CNT/EMULGEN 250 becomes 25/75, thereby preparing a solution.

This solution was mixed for 7 minutes by using a mechanical homogenizer to obtain a premix.

By using a thin film spin system high speed mixer, a dispersion treatment was performed on the obtained premix for 2 minutes at a circumferential speed of 10 m/sec and then for 5 minutes at a circumferential speed of 40 m/sec in a thermostatic bath with a temperature of 10° C. by a high speed spinning thin film dispersion method, thereby preparing a coating composition which becomes the thermoelectric conversion layer.

The Seebeck coefficient of the N-type thermoelectric conversion material was evaluated using ZEM-3 manufactured by Advance Riko Corporation. As a result, the Seebeck coefficient is −30 μV/K.

[Formation of P-Type Thermoelectric Conversion Layer and N-Type Thermoelectric Conversion Layer]

Regarding the P-Type thermoelectric conversion layer, using the above-described coating composition which becomes the above-described P-type thermoelectric conversion layer, the patterns of the coating composition were formed by metal mask printing by setting a squeegee direction to be the direction in which the thermoelectric conversion elements were connected to each other in series, under the conditions of an attack angle of 20°, a clearance of 1.5 mm, a printing pressure of 0.3 MPa, and an indentation amount of 0.1 mm, and dried for 5 minutes at 50° C. and then for 5 minutes at 120° C.

The N-type thermoelectric conversion layer was formed by metal mask printing using the above-described coating composition which becomes the above-described N-type thermoelectric conversion layer, under the same printing conditions as in the printing of the P-type thermoelectric conversion layer.

Next, the resultant was immersed in ethanol for 1 hour to remove sodium deoxycholate from the P-type thermoelectric conversion layer and the N-type thermoelectric conversion layer, and dried for 10 minutes at 50° C. and then for 120 minutes at 120° C. The P-type thermoelectric conversion layer and the N-type thermoelectric conversion layer after drying each had a size of vertical 5 mm and horizontal 3 mm and a thickness of 10 μm.

In the first example, Examples 1 to 5 and Comparative Example 1 were produced and a temperature difference of the thermoelectric conversion module body was evaluated. The normal stress in Examples 1 to 5 and Comparative Example 1 is shown in Table 1. In Table 1 below, “<0.01 MPa” indicates a normal stress of lower than 0.01 MPa.

Regarding the temperature of the thermoelectric conversion module body 13, a thin film thermocouple (manufactured by Anbe SMT Co.) was sandwiched between the connection electrode at the center portion of the thermoelectric conversion module body 13 in the x direction and the rear surface of the insulating substrate, and the temperature of the connection electrode of the thermoelectric conversion element was measured. Thus, a temperature difference of the thermoelectric conversion element at the center portion of the thermoelectric conversion module body was obtained. The temperature differences of Examples 1 to 5 and Comparative Example 1 are shown in Table 1 below.

The temperature difference was obtained under the following conditions. A hot plate at a temperature of 80° C. was used for the base 14, the side close to the base 14 was set to a high temperature side, and the side close to the heat dissipating fin 18 was set to a low temperature side. The temperature of the periphery of the heat dissipating fin 18 was set to 25° C.

### Example 1

Example 1 was configured such that in the configuration of the thermoelectric conversion device 10 shown in FIG. 1, the heat transfer portion was provided on only the high temperature side of the thermoelectric conversion module body.

### Example 2

Example 2 was configured such that in the configuration of the thermoelectric conversion device 10 shown in FIG. 1, the heat transfer portion was provided on only the low temperature side of the thermoelectric conversion module body.

### Example 3

Example 3 had the configuration of the thermoelectric conversion device 10 shown in FIG. 1, and the heat transfer portions were provided on both the high temperature side and the low temperature side of the thermoelectric conversion module body.

### Example 4

Example 4 had the configuration of the thermoelectric conversion device 10 shown in FIG. 1, and the heat transfer portions were provided on both the high temperature side and the low temperature side of the thermoelectric conversion module body.

### Example 5

Example 5 had the configuration of the thermoelectric conversion device 10 shown in FIG. 1, and the heat transfer portions were provided on both the high temperature side and the low temperature side of the thermoelectric conversion module body.

### Comparative Example 1

Comparative Example 1 was configured such that in the configuration of the thermoelectric conversion device 10 shown in FIG. 1, the heat transfer portion was not provided.

TABLE 1

| | Normal stress of | | Normal stress of | | | |
|---|---|---|---|---|---|---|
| | low temperature side | | high temperature side | | Temperature | |
| | connection electrode | | connection electrode | | difference | |
| Example 1 | 0.01 | MPa | <0.01 | MPa | Δ15° | C. |
| Example 2 | <0.01 | MPa | 0.01 | MPa | Δ15° | C. |
| Example 3 | 0.01 | MPa | 0.01 | MPa | Δ25° | C. |
| Example 4 | 0.1 | MPa | 0.1 | MPa | Δ29° | C. |
| Example 5 | 0.3 | MPa | 0.3 | MPa | Δ30° | C. |
| Comparative | <0.01 | MPa | <0.01 | MPa | Δ7° | C. |
| Example 1 | | | | | | |

As shown in Table 1, in Examples 1 and 2, the heat transfer portions were provided on either the high temperature side or the low temperature side to sandwich the thermoelectric conversion module body therebetween, and the normal stress was set to 0.01 MPa. However, compared to Comparative Example 1, a larger temperature difference was generated.

In Example 3, the heat transfer portions were provided on both sides to sandwich the thermoelectric conversion module body therebetween and the normal stress was set to 0.01 MPa. However, compared to Examples 1 and 2 in which the heat transfer portion was provided on one side, a larger temperature difference was generated.

In Example 4, the heat transfer portions were provided on both sides to sandwich the thermoelectric conversion module body therebetween and the normal stress was set to 0.1 MPa. In Example 4, in a case where the normal stress was higher than in Example 3, a larger temperature difference was generated than in Example 3.

In Example 5, the heat transfer portions were provided on both sides to sandwich the thermoelectric conversion module body therebetween and the normal stress was set to 0.3 MPa. As in Example 5, even at a higher normal stress than in Example 3, in a case where the normal stress was equal to or higher than a specific value, a difference from Example 4 was small and the temperature difference was saturated.

### Second Example

In a second example, thermoelectric conversion modules of Examples 6 to 9 were produced and the temperature difference was evaluated.

The second example is different from the above-described first example in that instead of using the heat transfer portion shown in FIG. 8, the heat transfer portion shown in FIG. 10 is used and the temperature difference is evaluated. Except this point, the second example is the same as the above-described first example and thus the detailed descriptions thereof are omitted. Since the normal stress measurement method, the temperature measurement method, and the temperature difference evaluation are the same as in the above-described first example, the detailed descriptions thereof are omitted.

In the second example, basically, the configuration of the thermoelectric conversion device 10a shown in FIG. 13 was used.

In the bellows structure body 52, an aluminum film having a thickness of 100 μm as the conductive layer 54 was used and a polyimide film having a thickness of 12.5 μm was used as the insulating layer 56.

Fifty thermoelectric conversion module substrates 20 were arranged in the inner portions 57 of the mountain fold portions of the bellows structure body 52 such that the direction of the insulating substrate 22 and the direction of the connection electrode 34 were aligned and gripped by using a vise.

The normal stress was adjusted by increasing or decreasing a force in a case of gripping the bellows structure body with a vise.

The temperature difference was measured in the same manner under the same conditions as in the above-described first example.

In the second example, in a case where the bellows structure body 52 was provided on only one side, no member was provided in the end portion of the insulating substrate 22 on a side on which the bellows structure body 52 was not provided, and each of the end portions of the plurality of insulating substrates 22 on a side on which the bellows structure body 52 was not provided was kept as it was without any particular treatment.

The normal stress and the temperature differences of Examples 6 to 9 and Comparative Example 1 are shown in Table 2 below. In Table 2 below, “<0.01 MPa” indicates a normal stress of lower than 0.01 MPa.

Hereinafter, Examples 6 to 9 will be described. Comparative Example 1 is the same as in the first example described above.

### Example 6

Example 6 was configured such that in the configuration of the thermoelectric conversion device 10a shown in FIG. 13, the bellows structure body 52 was provided on only the connection electrode on the high temperature side of the thermoelectric conversion module body (refer to FIG. 12).

### Example 7

Example 7 was configured such that in the configuration of the thermoelectric conversion device 10a shown in FIG. 13, the bellows structure body 52 was provided on only the connection electrode on the low temperature side of the thermoelectric conversion module body.

### Example 8

Example 8 had the configuration of the thermoelectric conversion device 10a shown in FIG. 13 and the bellows structure bodies 52 were provided on the connection electrodes on both the low temperature side and the high temperature side of the thermoelectric conversion module body.

### Example 9

Example 9 had the configuration of the thermoelectric conversion device 10a shown in FIG. 13 and the bellows structure bodies 52 were provided on the connection electrodes on both the low temperature side and the high temperature side of the thermoelectric conversion module body.

TABLE 2

| | Normal stress of | | Normal stress of | | | |
|---|---|---|---|---|---|---|
| | low temperature side | | high temperature side | | Temperature | |
| | connection electrode | | connection electrode | | difference | |
| Example 6 | 0.01 | MPa | <0.01 | MPa | Δ17° | C. |
| Example 7 | <0.01 | MPa | 0.01 | MPa | Δ17° | C. |
| Example 8 | 0.01 | MPa | 0.01 | MPa | Δ27° | C. |
| Example 9 | 0.3 | MPa | 0.3 | MPa | Δ32° | C. |
| Comparative | <0.01 | MPa | <0.01 | MPa | Δ7° | C. |
| Example 1 | | | | | | |

As shown in Table 2, in Examples 6 and 7, the bellows structure body was provided on one connection electrode and the normal stress was set to 0.01 MPa. However, a temperature difference was generated compared to Comparative Example 1.

In Example 8, the bellows structure bodies were provided on both connection electrodes and the normal stress was set to 0.01 MPa. However, a larger temperature difference was generated compared to Examples 6 and 7 in which the bellows structure body was provided on one side.

In Example 9, the bellows structure bodies were provided on both connection electrodes and the normal stress was set to 0.3 MPa. As in Example 9, in a case where the normal stress was higher than in Example 8, the temperature difference was larger than in Example 8.

### Third Example

In a third example, thermoelectric conversion modules of Examples 10 to 14 were produced and the temperature difference was evaluated.

The third example is different from the above-described second example in that the heat transfer portion shown in FIG. 8 of the first example is further provided, and the temperature difference is evaluated. Except this point, the third example is the same as the above-described second example, and thus the detailed descriptions thereof are omitted. Since the normal stress measurement method, the temperature measurement method, and the temperature difference evaluation are the same as in the above-described first example, the detailed descriptions thereof are omitted.

In the third example, basically, the configuration of the thermoelectric conversion device 10a shown in FIG. 14 was used. The third example has a configuration obtained by combining the first example and the second example.

The size of the outer frame 40 and the frame portion 42 of the heat transfer portion of the first example or the like used in the third example was the same as in the above-described first example.

In the third example, in a case where the bellows structure body 52 was provided on only one side, as in the second example, no member was provided in the end portion of the insulating substrate 22 on the side on which the bellows structure body 52 was not provided and each of the end portions of the plurality of insulating substrates 22 on the side on which the bellows structure body 52 was not provided was kept as it was without any particular treatment.

The normal stresses and the temperature differences of Examples 10 to 14 and Comparative Example 1 are shown in Table 3 below. In Table 3 below, “<0.01 MPa” indicates a normal stress of lower than 0.01 MPa.

Hereinafter, Examples 10 to 14 and Comparative Example 1 will be described. Comparative Example 1 is the same as in the above-described first example.

### Example 10

Example 10 was configured such that in the configuration of the thermoelectric conversion device 10b shown in FIG. 14, the heat transfer portion 16 was provided on only the high temperature side and the bellows structure body 52 was provided on only the connection electrode of the high temperature side of the thermoelectric conversion module body (refer to FIG. 12).

### Example 11

Example 11 was configured such that in the configuration of the thermoelectric conversion device 10b shown in FIG. 14, the heat transfer portion 16 was provided on only the low temperature side and the bellows structure body 52 was provided on only the connection electrode of the low temperature side of the thermoelectric conversion module body.

### Example 12

Example 12 had the configuration of the thermoelectric conversion device 10b shown in FIG. 14, and the bellows structure bodies 52 were provided on the connection electrodes of the low temperature side and the high temperature side of the thermoelectric conversion module body.

### Example 13

Example 13 had the configuration of the thermoelectric conversion device 10b shown in FIG. 14, and the bellows structure bodies 52 were provided on the connection electrodes of the low temperature side and the high temperature side of the thermoelectric conversion module body.

### Example 14

Example 14 had the configuration of the thermoelectric conversion device 10b shown in FIG. 14, and the bellows structure bodies 52 were provided on the connection electrodes of the low temperature side and the high temperature side of the thermoelectric conversion module body. The normal stress of Example 14 was measured with only super low pressure PRESCALE described above.

TABLE 3

| | Normal stress of | | Normal stress of | | | |
|---|---|---|---|---|---|---|
| | low temperature | | high temperature | | | |
| | side connection | | side connection | | Temperature | |
| | electrode | | electrode | | difference | |
| Example 10 | 0.01 | MPa | <0.01 | MPa | Δ17.5° | C. |
| Example 11 | <0.01 | MPa | 0.01 | MPa | Δ17.5° | C. |
| Example 12 | 0.01 | MPa | 0.01 | MPa | Δ33° | C. |
| Example 13 | 0.3 | MPa | 0.3 | MPa | Δ37° | C. |
| Example 14 | 1.0 | MPa | 1.0 | MPa | Δ40° | C. |
| Comparative | <0.01 | MPa | <0.01 | MPa | Δ7° | C. |
| Example 1 | | | | | | |

As shown in Table 3, in Examples 10 and 11, the bellows structure body was provided on one connection electrode, providing the heat transfer portions were further provided to sandwich the thermoelectric conversion module body therebetween, and the normal stress was set to 0.01 MPa. However, a temperature difference was generated compared to Comparative Example 1.

In Example 12, the bellows structure bodies were provided on both connection electrodes, the heat transfer portions further were provided to sandwich the thermoelectric conversion module body therebetween, and the normal stress was set to 0.01 MPa. However, the temperature difference was larger than in Examples 10 and 11 in which the bellows structure body was provided on one side.

In Example 13, the bellows structure bodies were provided on both connection electrodes, the heat transfer portions further were provided to sandwich the thermoelectric conversion module body therebetween, and the normal stress was set to 0.3 MPa. As in Example 13, in a case where the normal stress was higher than in Example 12, the temperature difference was larger than in Example 12.

In Example 14, the bellows structure bodies were provided on both connection electrodes, the heat transfer portions further were provided to sandwich the thermoelectric conversion module body therebetween, and the normal stress was set to 1.0 MPa. As in Example 14, in a case where the normal stress was higher than in Example 13, the temperature difference was larger than in Example 13.

### Fourth Example

In a fourth example, Examples 15 to 19 and Comparative Example 2 were produced and the temperature difference of the thermoelectric conversion module body was evaluated.

The fourth example is different from the above-described first example in that various materials are used for the frame portion and the temperature difference is evaluated. Except this point, the fourth example is the same as the above-described first example, and thus the detailed descriptions thereof are omitted. Since the normal stress measurement method, the temperature measurement method, and the temperature difference evaluation are the same as in the above-described first example, the detailed descriptions thereof are omitted.

The temperature difference was obtained under the following conditions. As a high temperature side heat source, a thermally conductive gel sheet was brought into contact with warm water at 80° C. (flow rate: 10 liter/min) through an aluminum plate having a thickness of 0.5 mm. As a low temperature side heat source, a thermally conductive gel sheet was brought into contact with cooling water at 12° C. (flow rate: 40 liter/min) through an aluminum plate having a thickness of 0.5 mm.

The size of the thermoelectric conversion module body, and the outer frame 40 and the frame portion 42 of the heat transfer portion of the first example or the like used in the fourth example was the same as in the above-described first example. The thermal conductivity values shown in Table 4 are values shown in Handbook of Physical Properties.

Hereinafter, Examples 15 to 19 and Comparative Example 2 will be described.

### Example 15

Example 15 was configured such that in the configuration of the thermoelectric conversion device 10 shown in FIG. 1, the normal stress was set to 0.01 MPa, and the frame portion was constituted of S50C (Japanese Industrial Standards (JIS) G4051:2005, carbon steel material for mechanical structures).

### Example 16

Example 16 was configured such that in the configuration of the thermoelectric conversion device 10 shown in FIG. 1, the normal stress was set to 0.01 MPa, and the frame portion was constituted of stainless steel Japanese Industrial Standards (JIS) SUS304.

### Example 17

Example 17 had the configuration of the thermoelectric conversion device 10 shown in FIG. 1, the normal stress was set to 0.01 MPa, and the frame portion was constituted of alumina.

### Example 18

Example 18 had the configuration of the thermoelectric conversion device 10 shown in FIG. 1, the normal stress was set to 0.01 MPa, and the frame portion was constituted of an aluminum alloy A5052 (Japanese Industrial Standards (JIS) H114000:2014).

### Example 19

Example 19 had the configuration of the thermoelectric conversion device 10 shown in FIG. 1, the normal stress was set to 0.01 MPa, and the frame portion was constituted of oxygen-free copper C1020P (Japanese Industrial Standards (JIS) H3100:2006).

### Comparative Example 2

Comparative Example 2 was the same configuration as in Example 15 except that the normal stress was set to 0.01 MPa, and the frame portion was constituted of soda glass.

TABLE 4

| | Frame portion | | | |
|---|---|---|---|---|
| | | Thermal conductivity | Temperature | |
| | Material | (w/mK) | difference | |
| Example 15 | S50C | 10 | Δ60° | C. |
| Example 16 | SUS304 | 17 | Δ65° | C. |
| Example 17 | Alumina | 24 | Δ67° | C. |
| Example 18 | A5052 | 236 | Δ75° | C. |
| Example 19 | C1020P | 398 | Δ75° | C. |
| Comparative | Soda glass | 1 | Δ37° | C. |
| Example 2 | | | | |

As shown in Table 4, in Examples 15 to 19, the frame portion constituted of the material having a thermal conductivity of 10 W/mK or higher, a large temperature difference was obtained. On the other hand, in Comparative Example 2, the frame portion was constituted of soda glass having a thermal conductivity of lower than 10 W/mK and the temperate difference was small.

In applications where the high temperature heat source and the low temperature heat source are fluids and sufficient heat flows are secured, in a case where the thermal conductivity of the material constituting the heat transfer portion is low, heat is not easily transferred to the connection electrode of the thermoelectric conversion module substrate.

### EXPLANATION OF REFERENCES

10, 10a, 10b, 10c, 10d, 10e, 10f, 10g, 10h: thermoelectric conversion device
12, 12a, 12b: thermoelectric conversion module
13: thermoelectric conversion module body
14: base
15: thermally conductive sheet
16, 50: heat transfer portion
18: heat dissipating fin
20, 20a: thermoelectric conversion module substrate
22: insulating substrate
22a: surface
22b: rear surface
24: P-type thermoelectric conversion element
26: N-type thermoelectric conversion element
28: through electrode
30: P-type thermoelectric conversion layer
32: N-type thermoelectric conversion layer
34: connection electrode
36: insulating sheet
40: outer frame
40a: inner surface
40b: inner surface
42: frame portion
42a: first frame material
42b: second frame material
42c: end surface
42d: recessed portion
42e: outer surface
43: heat transfer member
44: screw
52: bellows structure body
54: conductive layer
56: insulating layer
57: inner portion
60: linear member
62: end portion fixing member
64: magnetic force fixing member
70: pipe
70a: surface
D: longitudinal direction
DL, H, x, y: direction
Fp: pressing force
Rc, Rp: portion

What is claimed is:

1. A thermoelectric conversion module comprising:
a thermoelectric conversion module body which includes a plurality of thermoelectric conversion module substrates in which at least one of a P-type thermoelectric conversion element having a P-type thermoelectric conversion layer and a pair of connection electrodes which are electrically connected to the P-type thermoelectric conversion layer, or an N-type thermoelectric conversion element having an N-type thermoelectric conversion layer and a pair of connection electrodes which are electrically connected to the N-type thermoelectric conversion layer is provided on one surface of an insulating substrate having flexibility, the plurality of thermoelectric conversion module substrates being arranged such that a direction of the connection electrode and a direction of the insulating substrate are aligned; and
a heat transfer portion which is provided on a side of the thermoelectric conversion module body close to at least one connection electrode of the thermoelectric conversion module substrate, presses the thermoelectric conversion module substrate in an arrangement direction, and transfers heat to the thermoelectric conversion module body or dissipates heat of the thermoelectric conversion module body,
wherein a thermal conductivity of the heat transfer portion is 10 W/mK or higher, and
a normal stress in a direction perpendicular to a surface of the insulating substrate in a case of pressing the thermoelectric conversion module substrate in the arrangement direction by the heat transfer portion is 0.01 MPa or higher.

2. A thermoelectric conversion module comprising:
a thermoelectric conversion module body including a thermoelectric conversion module substrate which has a P-type thermoelectric conversion element having a P-type thermoelectric conversion layer and a pair of connection electrodes which are electrically connected to the P-type thermoelectric conversion layer, and an N-type thermoelectric conversion element having an N-type thermoelectric conversion layer and a pair of connection electrodes which are electrically connected to the N-type thermoelectric conversion layer provided on one surface of one insulating substrate having flexibility, and is alternately mountain-folded and valley-folded at the connection electrodes and formed in a bellows structure; and
a heat transfer portion which is provided on a side of the thermoelectric conversion module body close to at least one connection electrode of the thermoelectric conversion module substrate, presses the thermoelectric conversion module substrate in an arrangement direction, and transfers heat to the thermoelectric conversion module body or dissipates heat of the thermoelectric conversion module body,
wherein a thermal conductivity of the heat transfer portion is 10 W/mK or higher, and
a normal stress in a direction perpendicular to a surface of the insulating substrate in a case of pressing the thermoelectric conversion module substrate in the arrangement direction by the heat transfer portion is 0.01 MPa or higher.

3. The thermoelectric conversion module according to claim 1,
wherein the heat transfer portions are provided on sides of the thermoelectric conversion module body close to the both connection electrodes of the thermoelectric conversion module substrate, one heat transfer portion transfers heat to the thermoelectric conversion module body, and the other heat transfer portion dissipates heat of the thermoelectric conversion module body.

4. The thermoelectric conversion module according to claim 1,
wherein the heat transfer portion has a frame portion in contact with the thermoelectric conversion module body.

5. The thermoelectric conversion module according to claim 1,
wherein the heat transfer portion has a bellows structure body in which the connection electrode of the thermoelectric conversion module substrate of the thermoelectric conversion module body is sandwiched.

6. The thermoelectric conversion module according to claim 1,
wherein the heat transfer portion has a frame portion in contact with the thermoelectric conversion module body and a bellows structure body in which the connection electrode of the thermoelectric conversion module substrate of the thermoelectric conversion module body is sandwiched.

7. The thermoelectric conversion module according to claim 1,
wherein the thermoelectric conversion module substrate of the thermoelectric conversion module body is formed in a bellows-like shape.

8. The thermoelectric conversion module according to claim 1,
wherein the P-type thermoelectric conversion element and the N-type thermoelectric conversion element which are connected to each other in series by the connection electrodes are provided on the thermoelectric conversion module substrate.

9. The thermoelectric conversion module according to claim 1,
wherein the thermoelectric conversion module substrate on which only the P-type thermoelectric conversion element is provided and the thermoelectric conversion module substrate on which only the N-type thermoelectric conversion element is provided are alternately arranged in the arrangement direction in the thermoelectric conversion module body.

10. The thermoelectric conversion module according to claim 2,
wherein the heat transfer portions are provided on sides of the thermoelectric conversion module body close to the both connection electrodes of the thermoelectric conversion module substrate, one heat transfer portion transfers heat to the thermoelectric conversion module body, and the other heat transfer portion dissipates heat of the thermoelectric conversion module body.

11. The thermoelectric conversion module according to claim 2,
wherein the heat transfer portion has a frame portion in contact with the thermoelectric conversion module body.

12. The thermoelectric conversion module according to claim 3,
wherein the heat transfer portion has a frame portion in contact with the thermoelectric conversion module body.

13. The thermoelectric conversion module according to claim 3,
wherein the heat transfer portion has a bellows structure body in which the connection electrode of the thermoelectric conversion module substrate of the thermoelectric conversion module body is sandwiched.

14. The thermoelectric conversion module according to claim 3,
wherein the heat transfer portion has a frame portion in contact with the thermoelectric conversion module body and a bellows structure body in which the connection electrode of the thermoelectric conversion module substrate of the thermoelectric conversion module body is sandwiched.

15. The thermoelectric conversion module according to claim 3,
wherein the thermoelectric conversion module substrate of the thermoelectric conversion module body is formed in a bellows-like shape.

16. The thermoelectric conversion module according to claim 4,
wherein the thermoelectric conversion module substrate of the thermoelectric conversion module body is formed in a bellows-like shape.

17. The thermoelectric conversion module according to claim 2,
wherein the P-type thermoelectric conversion element and the N-type thermoelectric conversion element which are connected to each other in series by the connection electrodes are provided on the thermoelectric conversion module substrate.

18. The thermoelectric conversion module according to claim 3,
wherein the P-type thermoelectric conversion element and the N-type thermoelectric conversion element which are connected to each other in series by the connection electrodes are provided on the thermoelectric conversion module substrate.

19. The thermoelectric conversion module according to claim 3,
wherein the thermoelectric conversion module substrate on which only the P-type thermoelectric conversion element is provided and the thermoelectric conversion module substrate on which only the N-type thermoelectric conversion element is provided are alternately arranged in the arrangement direction in the thermoelectric conversion module body.

20. The thermoelectric conversion module according to claim 4,
wherein the thermoelectric conversion module substrate on which only the P-type thermoelectric conversion element is provided and the thermoelectric conversion module substrate on which only the N-type thermoelectric conversion element is provided are alternately arranged in the arrangement direction in the thermoelectric conversion module body.
